(19) United States
(12) Patent Application Publication
(10) Pub. No.: US 2025/0338611 A1
(43) Pub. Date: Oct. 30, 2025

(54) METAL CONTACT ISOLATION AND METHODS OF FORMING THE SAME

(71) Applicant: Taiwan Semiconductor Manufacturing Company, Ltd., Hsin-Chu (TW)

(72) Inventors: Lin-Yu Huang, Hsinchu (TW); Li-Zhen Yu, Taipei City (TW); Huan-Chieh Su, Changhua County (TW); Cheng-Chi Chuang, New Taipei City (TW); Chih-Hao Wang, Hsinchu County (TW)

(21) Appl. No.: 19/260,859

(22) Filed: Jul. 7, 2025

Related U.S. Application Data
(62) Division of application No. 17/729,893, filed on Apr. 26, 2022.
(60) Provisional application No. 63/233,115, filed on Aug. 13, 2021.

(51) Int. Cl. H10D 84/83; H01L 21/762; H01L 21/768; H10D 30/01; H10D 30/62; H10D 62/10; H10D 64/01; H10D 84/01; H10D 84/03

(52) U.S. Cl. CPC H10D 84/834; H01L 21/76224; H01L 21/76831; H10D 30/024; H10D 30/6211; H10D 30/6219; H10D 62/115; H10D 64/017; H10D 64/021; H10D 84/0158; H10D 84/038

(57) ABSTRACT

A method includes forming a fin protruding from a substrate, forming first and second dummy gates across the fin, depositing first and second gate spacers on sidewalls of the first and second dummy gates, respectively, forming a source/drain epitaxial feature over the fin and between the first and second dummy gates, depositing an interlayer dielectric layer over the source/drain epitaxial feature and between the first and second gate spacers, replacing the first and second dummy gates with first and second metal gates, respectively, patterning the interlayer dielectric layer to form an opening between the first and second gate spacers, forming a dielectric cut feature in the opening, after the forming of the dielectric cut feature, etching the interlayer dielectric layer to form a trench between the first and second metal gates, and forming a source/drain contact in the trench and in electrical coupling with the source/drain epitaxial feature.

### PRIORITY DATA

This is a divisional application of U.S. patent application Ser. No. 17/729,893, filed Apr. 26, 2022, which claims priority to U.S. Provisional Patent Application No. 63/233,115, filed Aug. 13, 2021, each of which is incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, forming isolation features between source/drain (S/D) metal contacts becomes more challenging when device sizes continue to decrease. Particularly, the limited spacing between S/D metal contacts increases risk of hard mask peel-off during patterning contact trenches and reduces device time dependent dielectric breakdown (TDDB) performance. Although methods for addressing such challenges have been generally adequate, they have not been entirely satisfactory in all aspects. An object of the present disclosure seeks to provide further improvements in the formation of metal contact isolation features among others.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a perspective view of a Fin Field-Effect Transistor (FinFET), in accordance with some embodiments.

FIGS. 2-7, 8A-8C, 9, 10A-10C, 11A-11C, 12A-12C, 13A-13C, 14A-14C, 15A-15C, 16A-16C, 17A-17C, 18A-18C, 19A-19C, 20A-20C, 21A-21C, 22A-22C, and 23A-23C illustrate various views (e.g., plan view and cross-sectional views) of a FinFET device at various stages of fabrication, in accordance with some embodiments.

FIGS. 24, 25, 26, 27, 28, and 29 are cross-sectional views of intermediate stages in the manufacturing of FinFET devices, in accordance with some alternative embodiments.

FIG. 30 illustrates a flow chart of a method of fabricating a semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

The present disclosure is generally related to semiconductor devices and the fabrication thereof, and more particularly to methods of fabricating field-effect transistors (FETs), such as fin-like FETs (FinFETs), nanostructure transistor (e.g., gate-all-around FETs (GAA FETs), nanosheet transistor, nanowire transistor, multi bridge channel FET, nano ribbon transistor), and/or other FETs. Some embodiments discussed herein are discussed in the context of FinFETs formed using a gate-last process. In other embodiments, a gate-first process may be used. Also, some embodiments contemplate aspects used in other types of multi-gate devices, such as nanostructure transistors, or planar devices, such as planar FETs.

In semiconductor fabrication, a source/drain (S/D) metal contact (hereafter referred to as an S/D contact) is formed over a top surface of an epitaxial S/D feature after a contact trench (also referred to as contact hole or contact opening) is formed over the epitaxial S/D feature. Isolation features are formed between S/D contacts as a contact end cut (also referred to as contact isolation or dielectric cut pattern) to isolate adjacent S/D contacts. However, with the development of technology nodes, the decreasing spacing between adjacent epitaxial S/D features, and accordingly decreasing spacing between adjacent S/D contacts, limits the process window of forming S/D contacts and contact isolations. For example, patterned hard mask overlying contact isolations for forming contact trenches may be peeled off during lithography process due to small sizes. Further, contact isolations filling limited spacing between S/D contacts with conventional oxide material may not be enough to meet needs of device time dependent dielectric breakdown (TDDB) performance. Embodiments of the present disclosure illustrate forming contact isolations stacked between adjacent gate structures along a fin lengthwise direction and separating adjacent S/D contacts along a gate structure lengthwise direction in a self-aligned manner. The formation of such contact isolations provides improvements to integrity of device manufacturing and device performance.

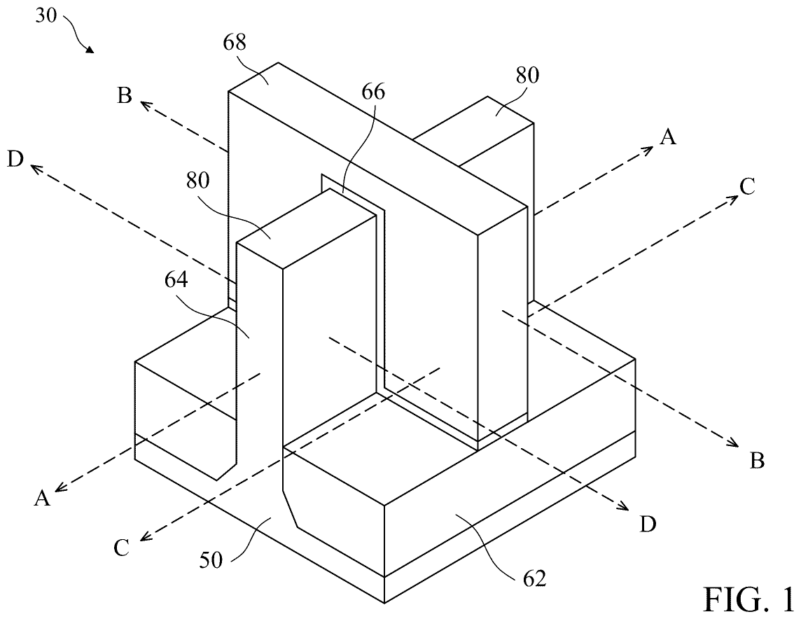

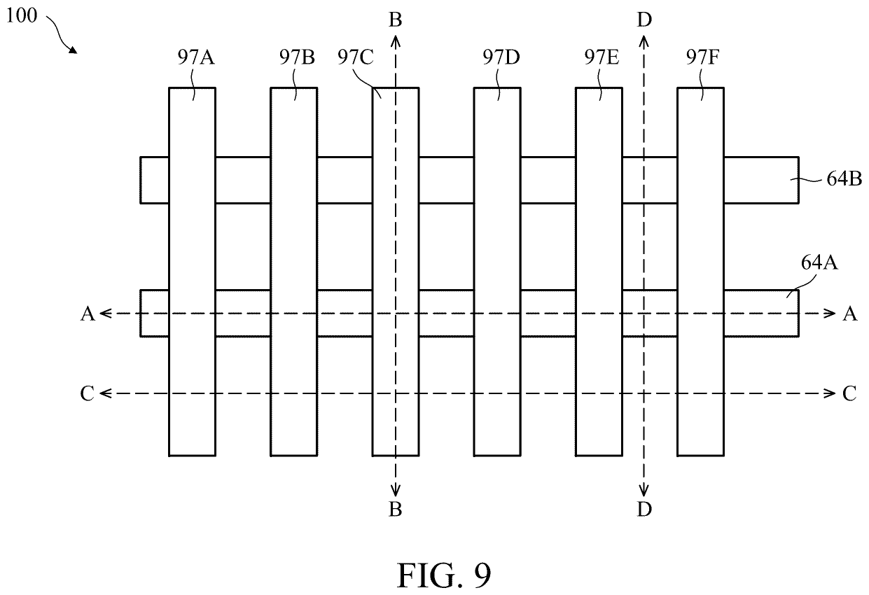

FIG. 1 illustrates an example of a FinFET 30 in a perspective view. The FinFET 30 includes a substrate 50 having a fin 64. The substrate 50 has isolation regions 62 formed thereon, and the fin 64 protrudes above and between neighboring isolation regions 62. A gate dielectric 66 is along sidewalls and over a top surface of the fin 64, and a gate electrode 68 is over the gate dielectric 66. S/D regions 80 are in the fin on opposite sides of the gate dielectric 66 and gate electrode 68. FIG. 1 further illustrates reference cross-sections that are used in later figures. Cross-section B-B extends along a longitudinal axis of the gate electrode 68 of the FinFET 30. Cross-section A-A is perpendicular to cross-section B-B and is along a longitudinal axis of the fin 64 and in a direction of, for example, a current flow between the S/D regions 80. Cross-section C-C is parallel to cross-section A-A and is outside the fin 64. Cross-section D-D is parallel to cross-section B-B and is outside the gate electrode 68, e.g., through the source/drain region 80. Cross-sections A-A, B-B, C-C, and D-D are also illustrated in the plan view of FIG. 9. Subsequent figures refer to these reference cross-sections for clarity.

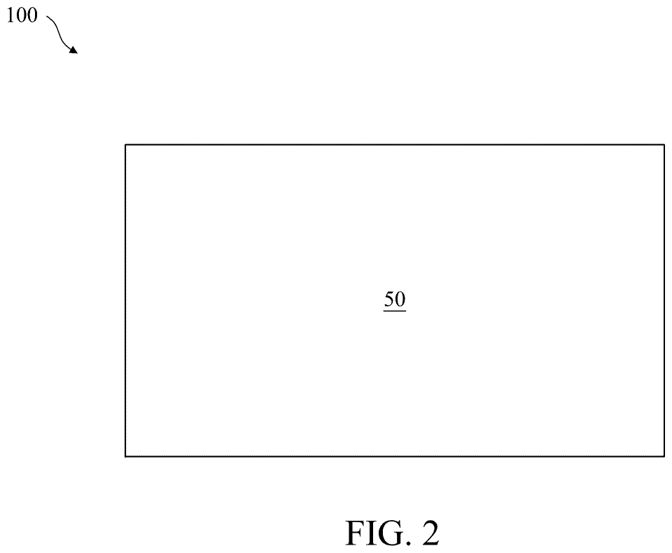

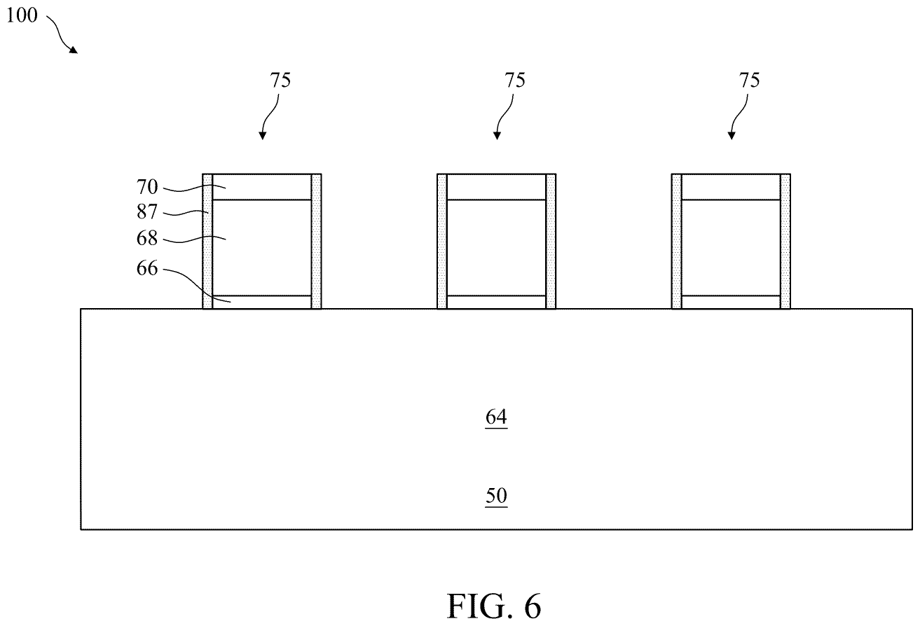

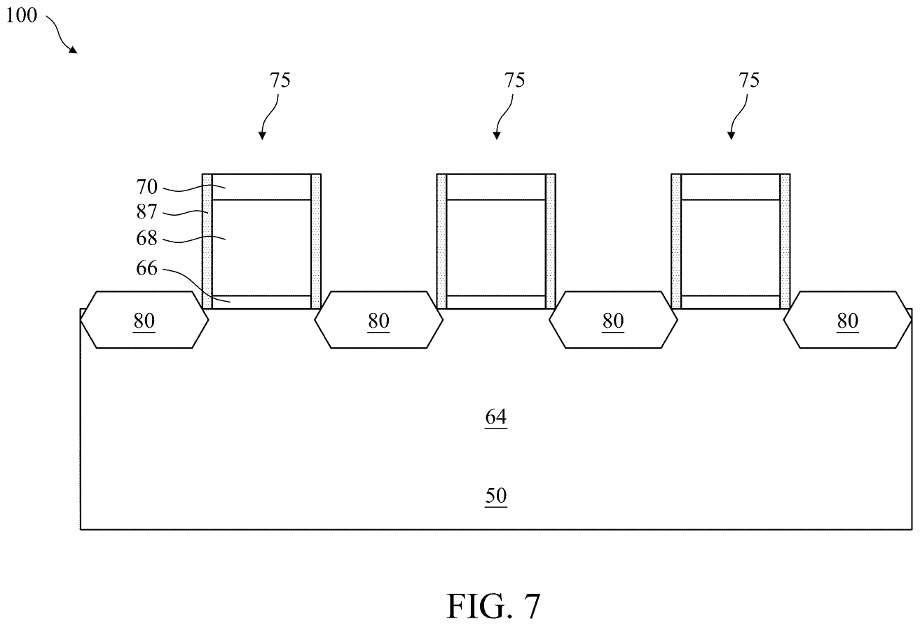

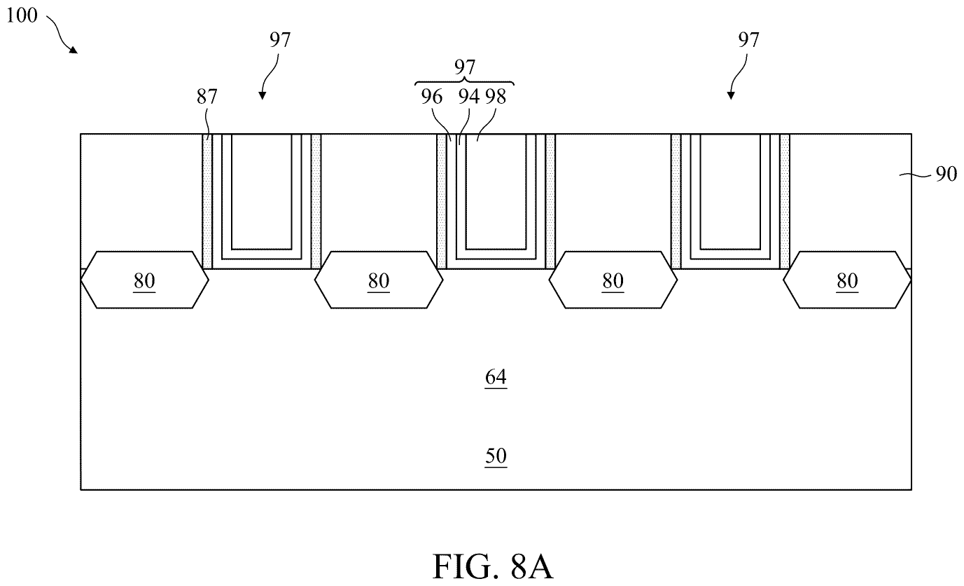

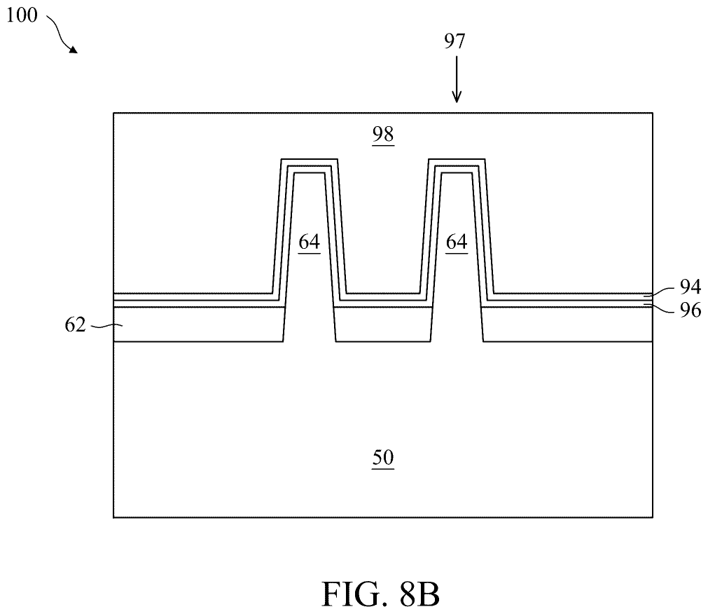

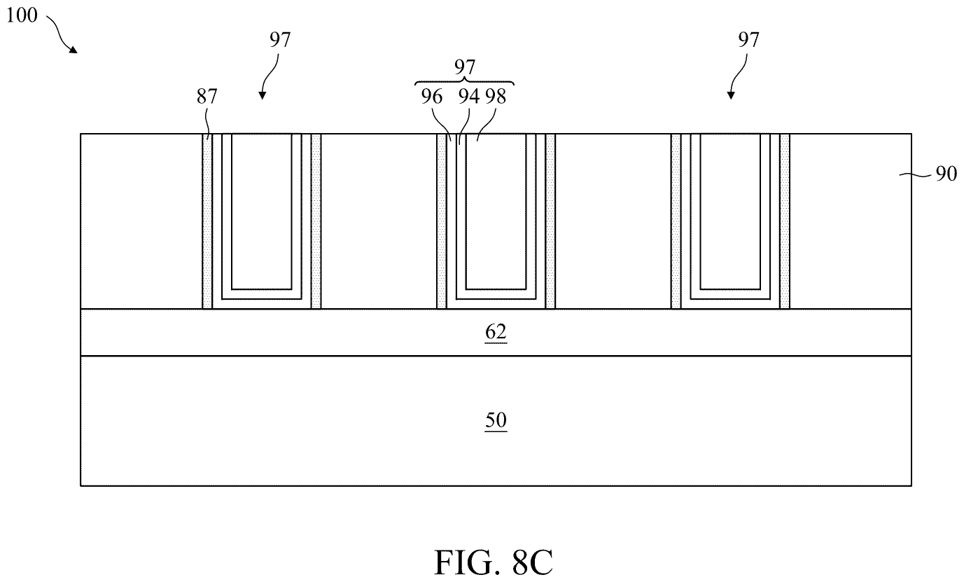

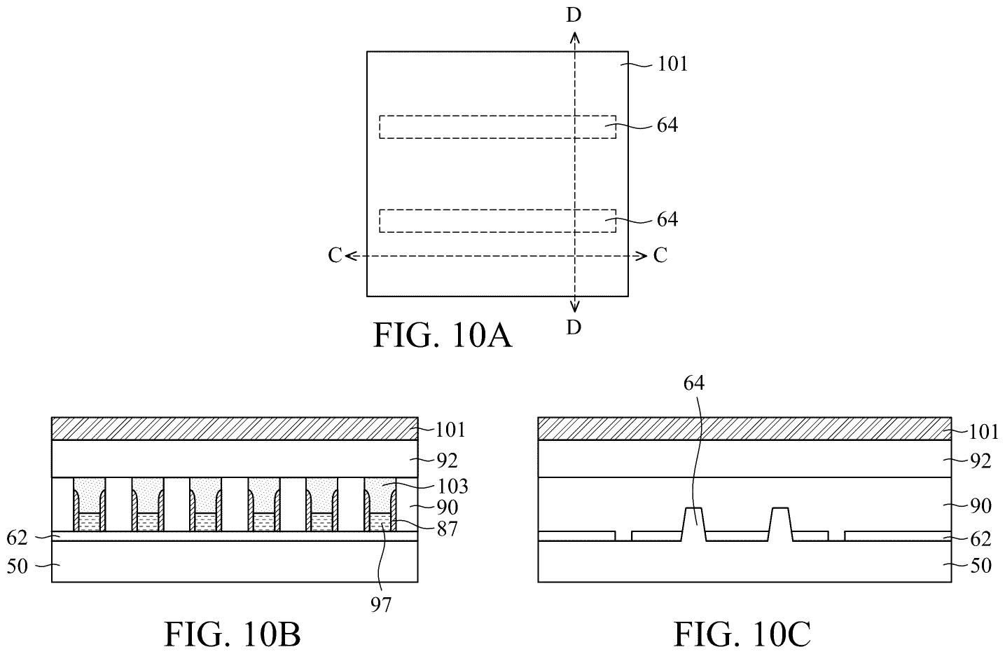

FIGS. 2-7, 8A-8C, 9, 10A-10C, 11A-11C, 12A-12C, 13A-13C, 14A-14C, 15A-15C, 16A-16C, 17A-17C, 18A-18C, 19A-19C, 20A-20C, 21A-21C, 22A-22C, and 23A-23C illustrate various views (e.g., plan view and cross-sectional views) of a FinFET device 100 at various stages of fabrication, in accordance with an embodiment. The FinFET device 100 is similar to the FinFET 30 in FIG. 1, except for multiple fins and multiple gate structures. FIGS. 2-5 illustrate cross-sectional views of the FinFET device 100 along cross-section B-B, and FIGS. 6 and 7 illustrate cross-sectional views of the FinFET device 100 along cross-section A-A. FIGS. 8A, 8B and 8C illustrate cross-sectional views of the FinFET device 100 along cross-section A-A, B-B and C-C, respectively. FIG. 9 is a plan view of the FinFET device 100. FIGS. 10A-23C illustrate cross-sectional views of the FinFET device 100 along different cross-sections at various stages of fabrication, where figures with the same numerals (e.g., 10A, 10B, and 10C) illustrate cross-sectional views of the FinFET device 100 at a same stage of processing. In particular, FIGS. 10A, 11A, 12A, 13A, 14A, 15A, 16A, 17A, 18A, 19A, 20A, 21A, 22A, and 23A illustrate top views of the FinFET device 100, FIGS. 10B, 11B, 12B, 13B, 14B, 15B, 16B, 17B, 18B, 19B, 20B, 21B, 22B, and 23B illustrate cross-sectional views of the FinFET device 100 along cross-section C-C of the respective top view, and FIGS. 10C, 11C, 12C, 13C, 14C, 15C, 16C, 17C, 18C, 19C, 20C, 21C, 22C, and 23C illustrate cross-sectional views of the FinFET device 100 along cross-section D-D of the respective top view. Note for that clarity, some Figures may show only a portion of the FinFET device 100, and not all features of the FinFET device 100 are illustrated in the Figures.

FIG. 2 illustrates a cross-sectional view of a substrate 50. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

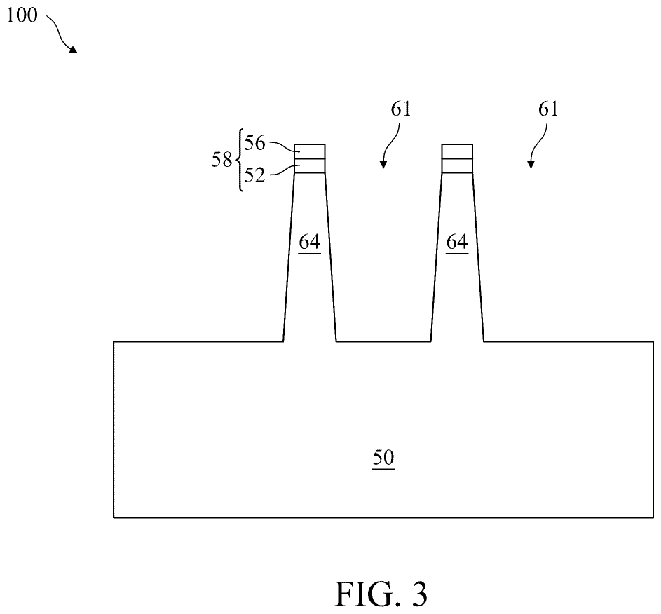

Referring to FIG. 3, the substrate 50 shown in FIG. 2 is patterned using, for example, photolithography and etching techniques. For example, a mask layer, such as a pad oxide layer 52 and an overlying pad nitride layer 56, is formed over the substrate 50. The pad oxide layer 52 may be a thin film comprising silicon oxide formed, for example, using a thermal oxidation process. The pad oxide layer 52 may act as an adhesion layer between the substrate 50 and the overlying pad nitride layer 56 and may act as an etch stop layer for etching the pad nitride layer 56. In some embodiments, the pad nitride layer 56 is formed of silicon nitride, silicon oxynitride, silicon carbide, silicon carbonitride, the like, or a combination thereof, and may be formed using low-pressure chemical vapor deposition (LPCVD) or plasma enhanced chemical vapor deposition (PECVD), as examples.

The mask layer may be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. In this example, the photoresist material is used to pattern the pad oxide layer 52 and pad nitride layer 56 to form a patterned mask 58, as illustrated in FIG. 3.

The patterned mask 58 is subsequently used to pattern exposed portions of the substrate 50 to form trenches 61, thereby defining semiconductor fins 64 (also referred to as fins 64) between adjacent trenches 61 as illustrated in FIG. 3. In some embodiments, the semiconductor fins 64 are formed by etching trenches in the substrate 50 using, for example, reactive ion etch (RIE), neutral beam etch (NBE), the like, or a combination thereof. The etch may be anisotropic. In some embodiments, the trenches 61 may be strips (viewed from in the top) parallel to each other, and closely spaced with respect to each other. In some embodiments, the trenches 61 may be continuous and surround the semiconductor fins 64. After semiconductor fins 64 are formed, the patterned mask 58 may be removed by etching or any suitable method.

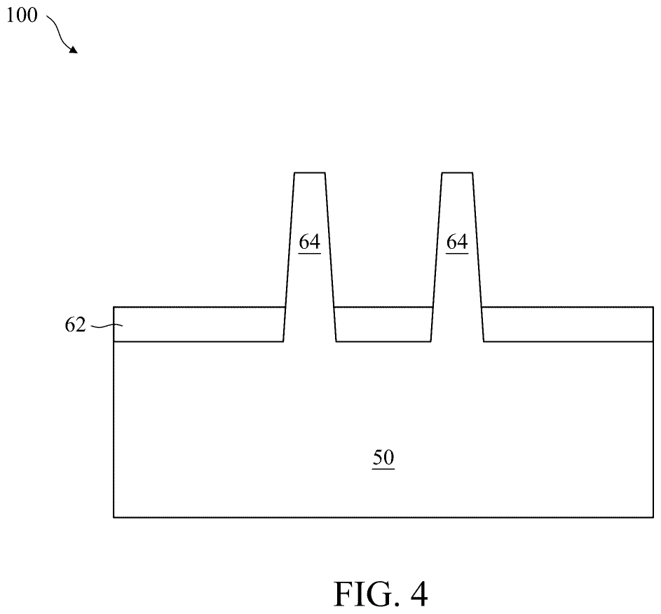

FIG. 4 illustrates the formation of an insulation material between neighboring semiconductor fins 64 to form isolation regions 62. The insulation material may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials and/or other formation processes may be used. In the illustrated embodiment, the insulation material is silicon oxide formed by an FCVD process. An anneal process may be performed once the insulation material is formed. A planarization process, such as a chemical mechanical polish (CMP), may remove any excess insulation material (and, if present, the patterned mask 58) and form top surfaces of the isolation regions 62 and top surfaces of the semiconductor fins 64 that are coplanar.

In some embodiments, the isolation regions 62 include a liner, e.g., a liner oxide (not shown), at the interface between the isolation regions 62 and the substrate 50 and the semiconductor fins 64. In some embodiments, the liner oxide is formed to reduce crystalline defects at such interface. The liner oxide (e.g., silicon oxide) may be a thermal oxide formed through a thermal oxidation of a surface layer of the substrate 50 and the semiconductor fins 64, although other suitable method may also be used to form the liner oxide.

Next, the isolation regions 62 are recessed to form shallow trench isolation (STI) regions (also referred to as STI features). The isolation regions 62 are recessed such that the upper portions of the semiconductor fins 64 protrude above upper surfaces of the isolation regions 62. The top surfaces of the isolation regions 62 may have a flat surface (as illustrated), a convex surface, a concave surface (such as dishing), or a combination thereof. The top surfaces of the isolation regions 62 may be formed flat, convex, and/or concave by an appropriate etch. The isolation regions 62 may be recessed using an acceptable etching process, such as one that is selective to the material of the isolation regions 62. For example, a chemical oxide removal using dilute hydrofluoric (dHF) acid may be used.

FIGS. 2 through 4 illustrate an embodiment of forming fins 64, but fins may be formed in various different processes. In one example, a dielectric layer can be formed over a top surface of a substrate; trenches can be etched through the dielectric layer; homoepitaxial structures can be epitaxially grown in the trenches; and the dielectric layer can be recessed such that the homoepitaxial structures protrude from the dielectric layer to form fins. In another example, heteroepitaxial structures can be used for the fins. For example, the semiconductor fins can be recessed, and a material different from the semiconductor fins may be epitaxially grown in their place. In an even further example, a dielectric layer can be formed over a top surface of a substrate; trenches can be etched through the dielectric layer; heteroepitaxial structures can be epitaxially grown in the trenches using a material different from the substrate; and the dielectric layer can be recessed such that the heteroepitaxial structures protrude from the dielectric layer to form fins. In some embodiments where homoepitaxial or heteroepitaxial structures are epitaxially grown, the grown materials may be in situ doped during growth, which may obviate prior and subsequent implantations although in situ and implantation doping may be used together. Still further, it may be advantageous to epitaxially grow a material in an NMOS region different from the material in a PMOS region. In various embodiments, the fins may comprise silicon germanium (SiₓGe₁₋ₓ, where x can be between approximately 0 and 1), silicon carbide, pure or substantially pure germanium, a III-V compound semiconductor, a II-VI compound semiconductor, or the like. For example, the available materials for forming III-V compound semiconductor include, but are not limited to, InAs, AlAs, GaAs, InP, GaN, InGaAs, InAlAs, GaSb, AlSb, AIP, GaP, and the like.

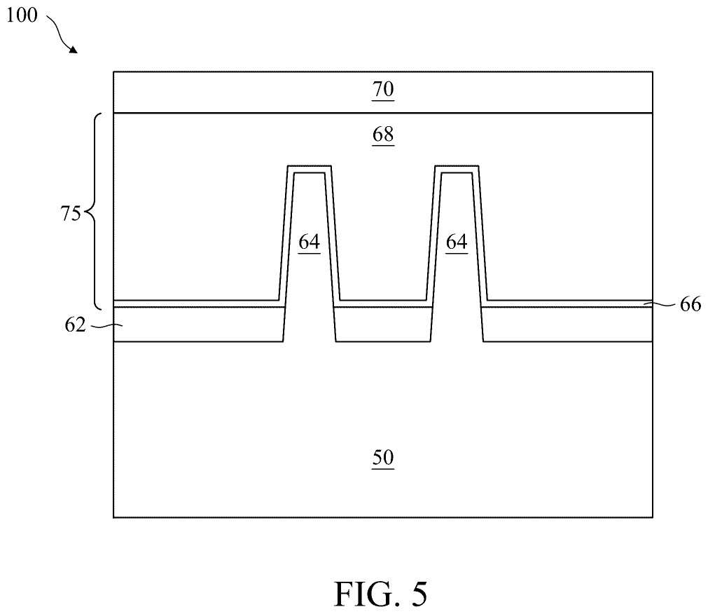

FIG. 5 illustrates the formation of a dummy gate structure 75 over the semiconductor fins 64. The dummy gate structure 75 includes a gate dielectric 66 and a gate electrode 68, in some embodiments. FIG. 5 further illustrates a mask 70 over the dummy gate structure 75. The dummy gate structure 75 may be formed by patterning a mask layer, a gate electrode layer and a gate dielectric layer. To form the dummy gate structure 75, the gate dielectric layer is formed on the semiconductor fins 64 and the isolation regions 62. The gate dielectric layer may be, for example, silicon oxide, silicon nitride, multilayers thereof, or the like, and may be deposited or thermally grown according to acceptable techniques. The formation methods of the gate dielectric layer may include molecular-beam deposition (MBD), atomic layer deposition (ALD), plasma-enhanced CVD (PECVD), and the like.

The gate electrode layer is formed over the gate dielectric layer, and the mask layer is formed over the gate electrode layer. The gate electrode layer may be deposited over the gate dielectric layer and then planarized, such as by a CMP process. The mask layer may be deposited over the gate electrode layer. The gate electrode layer may be formed of, for example, polysilicon, although other materials may also be used. The mask layer may be formed of, for example, silicon nitride or the like.

After the gate dielectric layer, the gate electrode layer, and the mask layer are formed, the mask layer may be patterned using acceptable photolithography and etching techniques to form the mask 70. The pattern of the mask 70 then may be transferred to the gate electrode layer and the gate dielectric layer by a suitable etching technique to form the gate electrode 68 and the gate dielectric 66, respectively. The gate electrode 68 and the gate dielectric 66 cover respective channel regions of the semiconductor fins 64. The gate electrode 68 may also have a lengthwise direction substantially perpendicular to the lengthwise direction of respective semiconductor fins 64. Although one dummy gate structure 75 is illustrated in the cross-sectional view of FIG. 5, more than one dummy gate structures 75 may be formed over the semiconductor fins 64. For example, the plan view in FIG. 9 illustrates multiple metal gates 97 (which replace the dummy gate structures in subsequent processing) over the semiconductor fins 64.

FIGS. 6-8A illustrate the cross-section views of further processing of the FinFET device 100 along cross-section A-A (along a longitudinal axis of the fin). As illustrated in FIG. 6, after the dummy gate structures 75 are formed, gate spacers 87 are formed on the gate structures. The gate spacers 87 are formed on opposing sidewalls of the gate electrode 68 and on opposing sidewalls of the gate dielectric 66. The gate spacers 87 may be formed of a nitride, such as silicon nitride, silicon oxynitride, silicon carbonitride, the like, or a combination thereof, and may be formed using, e.g., a thermal oxidation, CVD, or other suitable deposition process. The gate spacers 87 may also extend over the upper surface of the semiconductor fins 64 and the upper surface of the isolation region 62. The shapes and formation methods of the gate spacers 87 as illustrated in FIG. 6 are merely non-limiting examples, and other shapes and formation methods are possible. For example, the gate spacers 87 may include first gate spacers (not shown) and second gate spacers (not shown). The first gate spacers may be formed on opposing sidewalls of the dummy gate structure 75. The second gate spacers may be formed on the first gate spacers, with the first gate spacers disposed between a respective dummy gate structure 75 and the respective second gate spacers. The first gate spacers may have an L-shape in a cross-sectional view. As another example, the gate spacers 87 may be formed after the epitaxial S/D regions 80 (see FIG. 7) are formed. In some embodiments, dummy gate spacers are formed on the first gate spacers (not shown) before the epitaxial process of the epitaxial S/D regions 80 illustrated in FIG. 7, and the dummy gate spacers are removed and replaced with the second gate spacers after the epitaxial S/D regions 80 are formed. All such embodiments are fully intended to be included in the scope of the present disclosure.

Next, as illustrated in FIG. 7, S/D regions 80 are formed. The S/D regions 80 (also referred to as S/D features) are formed by etching the fins 64 to form recesses, and epitaxially growing a semiconductor material in the recess, using suitable methods such as metal-organic CVD (MOCVD), molecular beam epitaxy (MBE), liquid phase epitaxy (LPE), vapor phase epitaxy (VPE), selective epitaxial growth (SEG), the like, or a combination thereof. The epitaxial S/D regions 80 may have surfaces raised from respective surfaces of the fins 64 (e.g. raised above the non-recessed portions of the fins 64) and may have facets. The S/D regions 80 of the adjacent fins 64 may merge to form a continuous epitaxial source/drain region 80. In some embodiments, the S/D regions 80 of adjacent fins 64 do not merge together and remain separate S/D regions 80. In some example embodiments in which the resulting FinFET is an n-type FinFET, S/D regions 80 comprise silicon carbide (SiC), silicon phosphorous (SiP), phosphorous-doped silicon carbon (SiCP), or the like. In alternative example embodiments in which the resulting FinFET is a p-type FinFET, S/D regions 80 comprise SiGe, and a p-type impurity such as boron or indium.

The epitaxial S/D regions 80 may be implanted with dopants to form S/D regions 80 followed by an anneal process. The implanting process may include forming and patterning masks such as a photoresist to cover the regions of the FinFET that are to be protected from the implanting process. The S/D regions 80 may have an impurity (e.g., dopant) concentration in a range from about 1E19 cm⁻³ to about 1E21 cm⁻³. In some embodiments, the epitaxial source/drain regions may be in-situ doped during growth.

Next, as illustrated in FIG. 8A, a first interlayer dielectric (ILD) 90 is formed over the structure illustrated in FIG. 7, and a gate-last process (sometimes referred to as replacement gate process) is performed. In a gate-last process, the gate electrode 68 and the gate dielectric 66 (see FIG. 7) are considered dummy structures and are removed and replaced with an active gate electrode and active gate dielectric. The active gate electrode and active gate dielectric may be collectively referred to as a replacement gate or a metal gate.

In some embodiments, the first ILD 90 is formed of a dielectric material such as silicon oxide (SiO), phosphosilicate glass (PSG), borosilicate glass (BSG), boron-doped phosphosilicate Glass (BPSG), undoped silicate glass (USG), or the like, and may be deposited by any suitable method, such as CVD, PECVD, or FCVD. A planarization process, such as a CMP process, may be performed to remove the mask 70 and to planarize the top surface of the first ILD 90, such that the top surface of the first ILD 90 is level with the top surface of the gate electrode 68 (see FIG. 7) after the CMP process. Therefore, after the CMP process, the top surface of the gate electrode 68 is exposed, in some embodiments.

In accordance with some embodiments, the gate electrode 68 and the gate dielectric 66 directly under the gate electrode 68 are removed in an etching step(s), so that recesses (not shown) are formed. Each recess exposes a channel region of a respective fin 64. Each channel region may be disposed between neighboring pairs of epitaxial S/D regions 80. During the dummy gate removal, the dummy gate dielectric 66 may be used as an etch stop layer when the dummy gate electrode 68 is etched. The dummy gate dielectric 66 may then be removed after the removal of the dummy gate electrode 68.

Next, metal gates 97 are formed in the recesses by forming a gate dielectric layer 96, a work function metal (WFM) layer 94, and a gate electrode 98 successively in each of the recesses. As illustrated in FIG. 8A, the gate dielectric layer 96 is deposited conformally in the recesses. The WFM layer 94 is formed conformally over the gate dielectric layer 96, and the gate electrode 98 fills the recesses. Although not shown, a barrier layer may be formed, e.g., between the WFM layer 94 and the gate electrode 98.

In accordance with some embodiments, the gate dielectric layer 96 comprises silicon oxide, silicon nitride, or multilayers thereof. In other embodiments, the gate dielectric layer 96 includes a high-k dielectric material, and in these embodiments, the gate dielectric layers 96 may have a k value greater than about 7.0, and may include a metal oxide or a silicate of Hf, Al, Zr, La, Mg, Ba, Ti, Pb, and combinations thereof. The formation methods of gate dielectric layer 96 may include MBD, ALD, PECVD, and the like.

The WFM layer 94 may be formed conformally over the gate dielectric layer 96. The WFM layer 94 comprises any suitable material for a work function layer. Exemplary p-type work function metals that may be included in the WFM layer 94 include TiN, TaN, Ru, Mo, Al, WN, ZrSi₂, MoSi₂, TaSi₂, NiSi₂, WN, other suitable p-type work function materials, or combinations thereof. Exemplary n-type work function metals that may be included in the WFM layer 94 include Ti, Ag, TaAl, TaAIC, TiAlN, TaC, TaCN, TaSiN, Mn, Zr, other suitable n-type work function materials, or combinations thereof. A work function value is associated with the material composition of the work function layer, and thus, the material of the first work function layer is chosen to tune its work function value so that a target threshold voltage Vt is achieved in the device that is to be formed in the respective region. The WFM layer 94 may be deposited by CVD, PVD, ALD, and/or other suitable process. Next, a barrier layer (not shown) is formed conformally over the WFM layer 94. The barrier layer may comprise an electrically conductive material such as titanium nitride, although other materials, such as tantalum nitride, titanium, tantalum, or the like, may alternatively be utilized. The barrier layer may be formed using a CVD process, such as PECVD. However, other alternative processes, such as sputtering or MOCVD, ALD, may alternatively be used.

Next, the gate electrode 98 is formed over the barrier layer. The gate electrode 98 may be made of a metal-containing material such as Cu, Al, W, the like, combinations thereof, or multi-layers thereof, and may be formed by, e.g., electroplating, electroless plating, PVD, CVD, or other suitable method. A planarization process, such as a CMP, may be performed to remove the excess portions of the gate dielectric layer 96, the work function metal layer 94, the barrier layer, and the material of the gate electrode 98, which excess portions are over the top surface of the first ILD 90. The resulting remaining portions of material of the gate electrode 98, the barrier layer, the WFM layer 94, and the gate dielectric layer 96 thus form metal gates 97 of the FinFET device 100. Three metal gates 97 are illustrated in the example of FIG. 8A. However, more or less than three metal gates 97 may be used to form the FinFET device 100, as skilled artisans readily appreciate.

FIGS. 8B and 8C illustrate the FinFET device 100 of FIG. 8A, but along cross-section B-B and C-C, respectively. FIG. 8B shows the fins 64 and the metal gate 97 over the fins 64. FIG. 8C illustrates the gate spacers 87 and the metal gates 97 over the STI features 62. Note that the fin 64 is not visible in the cross-section of FIG. 8C.

Referring now to FIG. 9, a plan view of the FinFET device 100 after the processing step of FIGS. 8A-8C is illustrated. For simplicity, not all features of the FinFET device 100 are illustrated. For example, the gate spacers 87, the isolation regions 62, and the S/D regions 80 are not illustrated in FIG. 9. As illustrated in FIG. 9, the metal gates 97 (e.g., 97A/97B/97C/97D/97E/97F) straddle the semiconductor fins 64 (e.g., 64A/64B). In subsequent processing, a first plurality of cut patterns are formed between (or adjacent to) the metal gates 97. The cut patterns will be used to cut (e.g., separate) an electrically conductive material into separate portions, thereby defining S/D contacts in a self-aligned manner. A second plurality of cut patterns are subsequently used to separate an electrically conductive material into separate portions, thereby forming gate contact plugs in a self-aligned manner. Details are discussed hereinafter.

Referring now to FIGS. 10A-10C, FIG. 10A illustrates a top view of the FinFET device 100. The fins 64 are illustrated in phantom in FIG. 10A. The locations of the metal gates 97 (which correspond to the locations of the dielectric layer 103) are not illustrated in FIG. 10A. FIG. 10B illustrates the cross-sectional view of the FinFET device 100 along cross-section C-C, and FIG. 10C illustrates the cross-sectional view of the FinFET device 100 along cross-section D-D. Note that for simplicity, details of the metal gates 97 (e.g., the gate electrode 98, the WFM layer 94, and the gate dielectric layer 96) are not illustrated in FIG. 10B and subsequent figures.

As illustrated in FIGS. 10A-10C, the metal gates 97 are recessed below upper surfaces of the gate spacers 87, e.g., by an anisotropic etching process. As a result, recesses are created between the gate spacers 87 by the recessing of the metal gates 97. Top portions of the gate spacers 87 may also be removed by the anisotropic etching process, as illustrated in FIG. 10B. Next, a dielectric layer 103 (also referred to as self-aligned contact (SAC) layer) is formed to fill the recesses between the gate spacers 87. The dielectric layer 103 may comprise a suitable dielectric material such as SiC, LaO, AlO, AION, ZrO, HfO, SiN, Si, ZnO, ZrN, ZrAIO, TiO, TaO, YO, TaCN, ZrSi, SiOCN, SiOC, SiCN, HfSi, SiO, or the like, and may be formed by a suitable formation method such as CVD, PVD, the like, or combinations thereof. The dielectric layer 103 may be formed in a self-aligned manner, and sidewalls of the dielectric layer 103 may be aligned with respectively sidewalls of the gate spacers 87. A planarization process, such as CMP, may be performed to planarize the upper surface of the dielectric layer 103. After the dielectric layer 103 is formed, a dielectric layer 92, which may be the same as or similar to the first ILD 90, is formed over the first ILD 90 and over the dielectric layer 103, and thereafter, a hard mask layer 101 (e.g., an oxide or a nitride layer) is formed over the dielectric layer 92. In an example embodiment, the first ILD 90 and the dielectric layer 92 are both formed of an oxide (e.g., silicon oxide), and therefore, the first ILD 90 and the dielectric layer 92 may be collectively referred as an oxide 90/92 hereinafter. FIG. 10C illustrates the cross-sectional view of the FinFET device 100 along cross-section D-D. FIG. 10C shows the fins 64 protruding above the substrate 50 and the STI features 62. FIG. 10 C further illustrates the first ILD 90, the dielectric layer 92, and the hard mask layer 101.

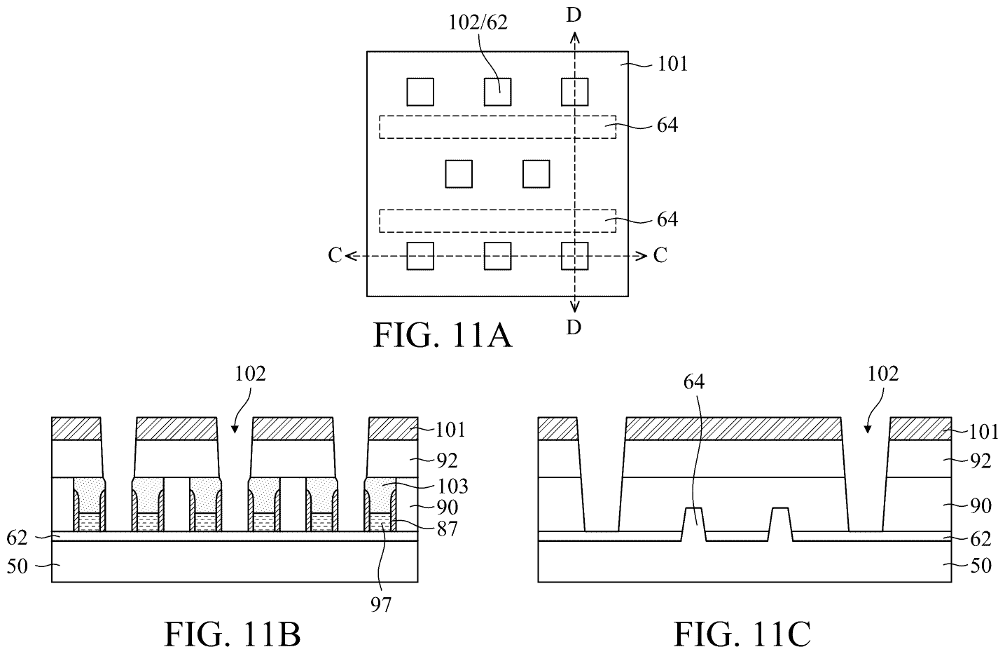

Next, in FIGS. 11A-11C, openings 102 are formed in the hard mask layer 101 to pattern the hard mask layer 101. The openings 102 are formed at locations between metal gates 97, and are spaced apart from the fins 64. A suitable method, such as photolithography and etching, may be used to form the openings 102. Once formed, the patterned hard mask layer 101 is used as an etching mask to pattern the dielectric layer 92 and the first ILD 90 using an etching process, such as an isotropic etching process. The etching process removes portions of the dielectric layer 92 and portions of the first ILD 90. When the etching process reaches the dielectric layer 103, the openings 102 narrows as the opening 102 may be wider than the width of the metal gates 97. As illustrated in FIGS. 11B and 11C, the openings 102 are extended into the first ILD 90, and have slanted sidewalls. For example, a width of the opening 102 may decrease as the opening 102 extends toward the substrate 50. Portions of the STI features 62 underlying the openings 102 may be exposed after the etching process. In the example of FIG. 11B, the sidewalls of the dielectric layer 103 and the sidewalls of the gate spacers 87 are exposed by the openings 102. The limiting etch selectivity may cause the top portion of the dielectric layer 103 to have rounded corners exposed in the openings 102.

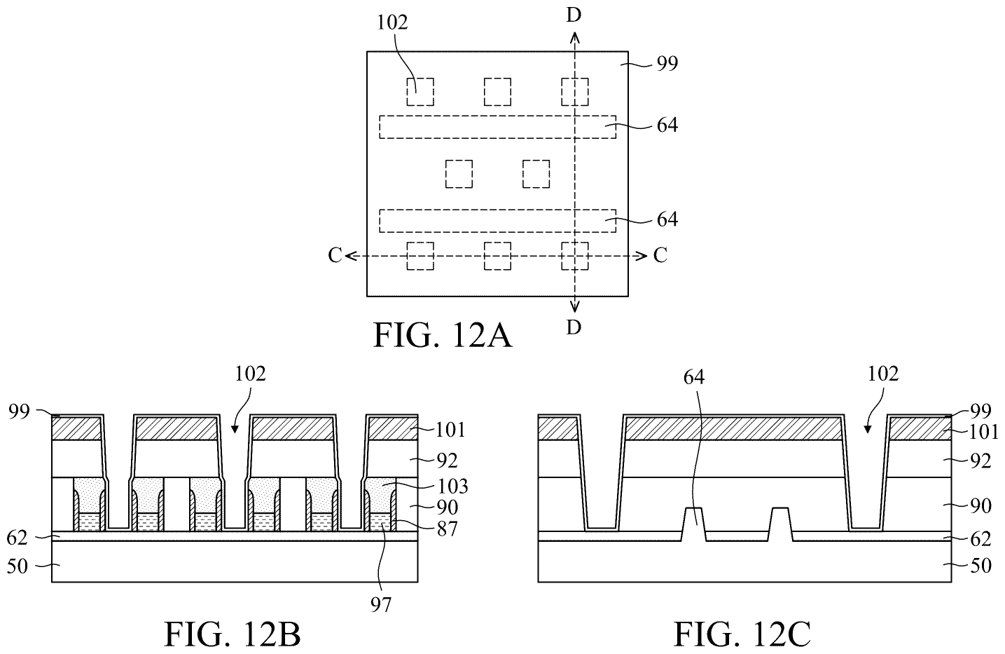

Next, in FIGS. 12A-12C, a liner 99 is formed along sidewalls of the structure shown in FIGS. 11A-11C and over exposed top surfaces of the STI features 62. The liner 99 may be formed by forming a conformal liner layer (e.g., a dielectric layer) over the FinFET device 100. The liner 99 is formed of a dielectric material, such as SiC, SiN, Si, ZrN, TaCN, ZrSi, SiCN, HfSi, or the like, in some embodiments. In some embodiments, a thickness of the liner 99 ranges from about 1 nm to about 10 nm.

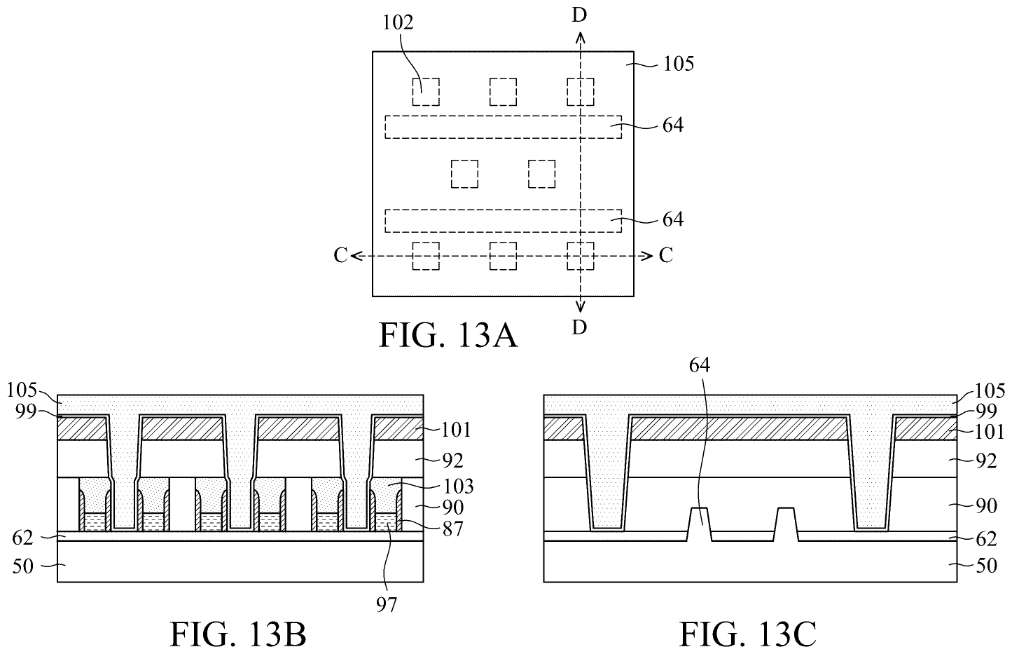

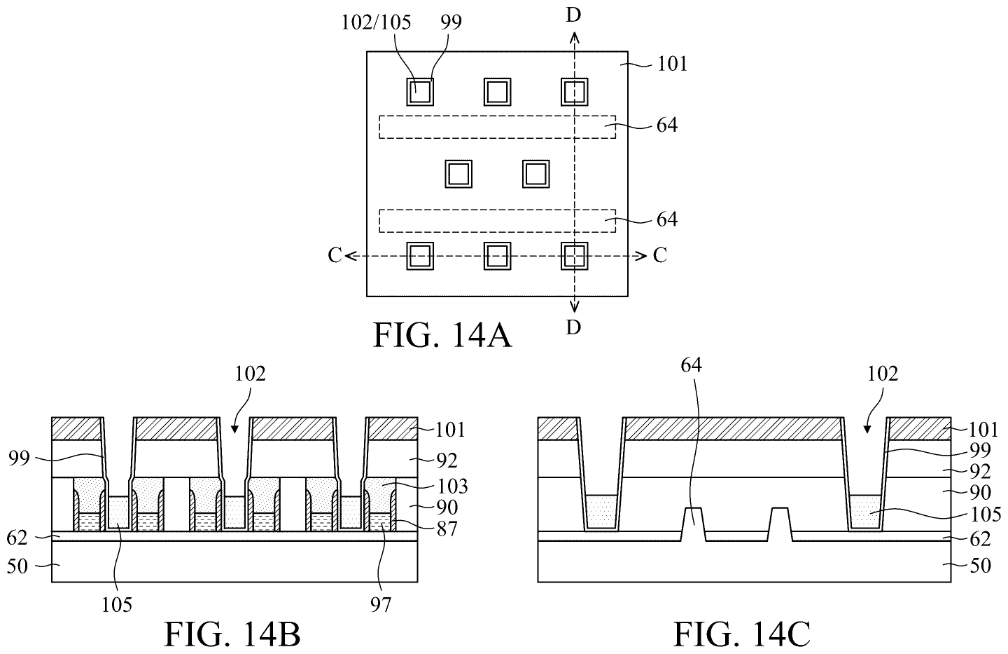

Next, in FIGS. 13A-13C and 14A-14C, a dielectric material 105 is formed to fill the openings 102. In some embodiments, the dielectric material 105 comprises SiC, LaO, AlO, AION, ZrO, HfO, SiN, Si, ZnO, ZrN, ZrAIO, TiO, TaO, YO, TaCN, ZrSi, SiOCN, SiOC, SiCN, HfSi, SiO, or the like, and is formed by a suitable formation method such as CVD, PVD, the like, or combinations thereof, such as shown in FIGS. 13A-13C. A planarization process, such as a CMP process, may be performed to remove excess portions of the dielectric material 105. Portions of the liner 99 disposed on top surfaces of the hard mask layer 101 may also be removed by the CMP process, such that the top surface of the hard mask layer 101 is exposed after the CMP process. Subsequently, the dielectric material 105 is recessed such that portions of the liner 99 disposed on top portion of the sidewalls of the opening 102 are exposed. After the recessing process, the dielectric material 105 partially fills the openings 102, such as shown in FIGS. 14A-14C. The recessed dielectric material 105 may have a height ranging from about 1 nm to about 80 nm. The recessing process may include dry etching, wet etching, reactive ion etching (RIE), and/or other suitable processes. In an alternative embodiment, after the deposition of the liner 99, a liner break-through process (such as an anisotropic etching process) may be performed, such that horizontal portions of the liner 99 is removed, such that the isolation regions 62 are exposed in the openings 102 and the top portions of the dielectric layer 103 (e.g., rounded corners) are also exposed in the openings 102. In such an alternative embodiment, the recessed dielectric material 105 is in contact with the isolation regions 62.

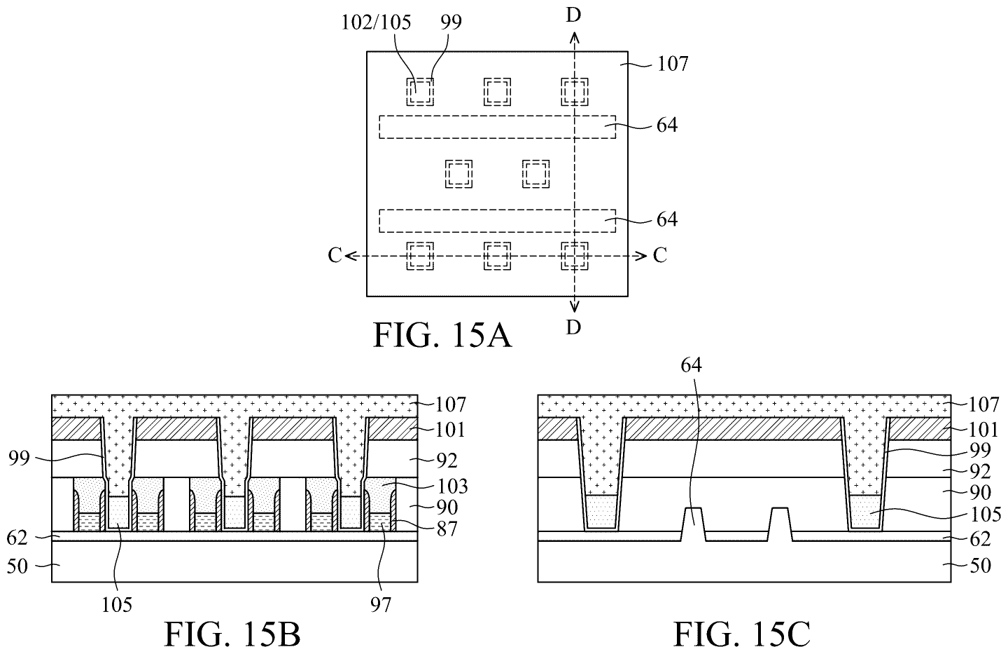

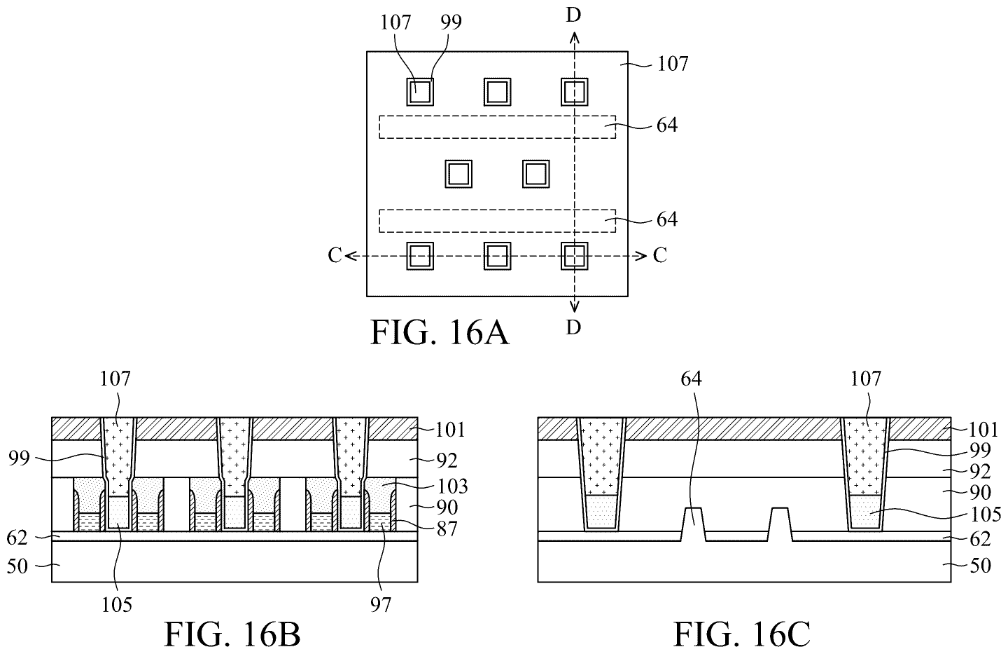

Next, in FIGS. 15A-15C and 16A-16C, a dielectric material 107 different (e.g., having a different composition) from the dielectric material 105 is formed over the dielectric material 105 to fill remaining portions of the openings 102. The dielectric material 107 is different (e.g., having a different composition) from the dielectric layer 103 to provide etching selectivity in subsequent processing. In some embodiments, the dielectric material 107 comprises SiC, LaO, AlO, AION, ZrO, HfO, SiN, Si, ZnO, ZrN, ZrAlO, TiO, TaO, YO, TaCN, ZrSi, SiOCN, SiOC, SiCN, HfSi, SiO, or the like, and is formed by a suitable formation method such as CVD, PVD, the like, or combinations thereof. The dielectric material 107 may be formed over the upper surface of the hard mask layer 101, such as shown in FIGS. 15A-15C. In some embodiments, due to the liner break-through process discussed above, the dielectric material 107 may be in contact with the exposed top portions of the dielectric layer 103 (e.g., with rounded corners of the dielectric layer 103). In some embodiments, a planarization process, such as a CMP process, is performed to remove excess portions of the dielectric material 107 from the upper surface of the hard mask layer 101. In other embodiments, the planarization process is omitted, and the portions of the dielectric material 107 over the upper surface of the hard mask layer 101 are removed, such as shown in FIGS. 16A-16C.

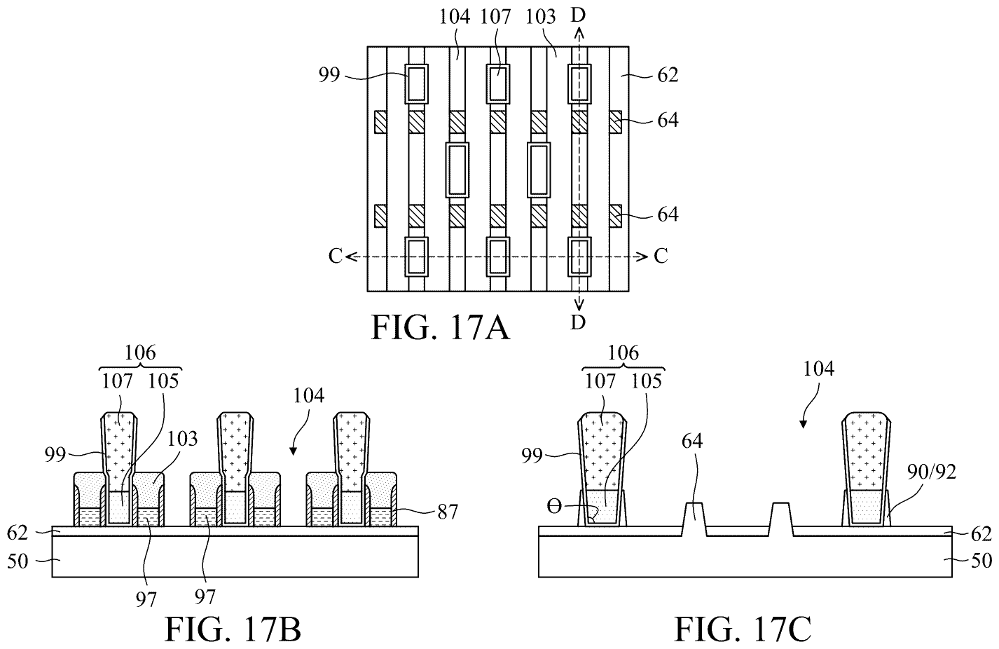

Next, in FIGS. 17A-17C, the hard mask layer 101 and portions of the dielectric material 107 over/in the hard mask layer 101, if any, are removed. In addition, the first ILD 90 and the dielectric layer 92 are also removed, and the fins 64 are exposed. Removal of the hard mask layer 101, portions of the dielectric material 107, the first ILD 90, and the dielectric layer 92 is performed by one or more suitable etching processes, such as a CMP process, a dry etch process (e.g., a plasma process), a wet etch process, the like, or combinations thereof. For example, a CMP process may be performed first to remove the hard mask layer 101 and portions of the dielectric material 107 over/in the hard mask layer 101. Next, an etching process (e.g., a dry etch or a wet etch) using an etchant that is selective to (e.g., having a higher etch rate for) the materials of the first ILD 90 and the dielectric layer 92 may be performed to remove the first ILD 90 and the dielectric layer 92.

In the example of FIG. 17A-17C, each of the metal gates 97 is directly under respective portions of the dielectric layer 103. Therefore, in the top view of FIG. 17A, each metal gate 97, with the respective gate spacers 87, has a same boundary as the respective portion of the dielectric layer 103. As a result, locations of the dielectric layer 103 in the top views correspond to locations of the metal gates 97. FIG. 17A therefore shows that each of the metal gates 97 extends continuously across the illustrated fins 64.

After the dielectric layer 92 and the first ILD 90 are removed, contact openings 104 (also referred to as contact trenches) are formed between adjacent metal gates 97. The openings 104 expose sidewalls of the gate spacers 87 that face away from the respective metal gate 97, and expose sidewalls of the dielectric layer 103. The fins 64 are also exposed. Due to the etching selective in removing the first ILD 90, the contact openings 104 are formed in a self-aligned manner. In the discussion hereinafter, the dielectric material 105 and the overlying dielectric material 107 that are in the same opening 104 are collectively referred to as a contact isolation feature 106, or a contact isolation 106. Since the contact isolation 106 cuts to-be-formed metal contacts into segments, the contact isolation 106 is also termed as dielectric cut pattern 106. For example, FIG. 17A illustrates eight dielectric cut patterns 106. FIG. 17C illustrates tapered sidewalls of the dielectric cut patterns 106, which are formed due to the tapered sidewalls of the openings 102 (see FIGS. 14B and 14C), in some embodiments. The tapered sidewall has an angle ⊖ with respect to the top surface of the substrate 50 in a range from about 92° to about 100°. FIG. 17C further illustrates residue portions of the oxide 90/92 that are along the tapered sidewalls of the dielectric cut patterns 106. In some embodiments, the oxide 90/92 is completely removed.

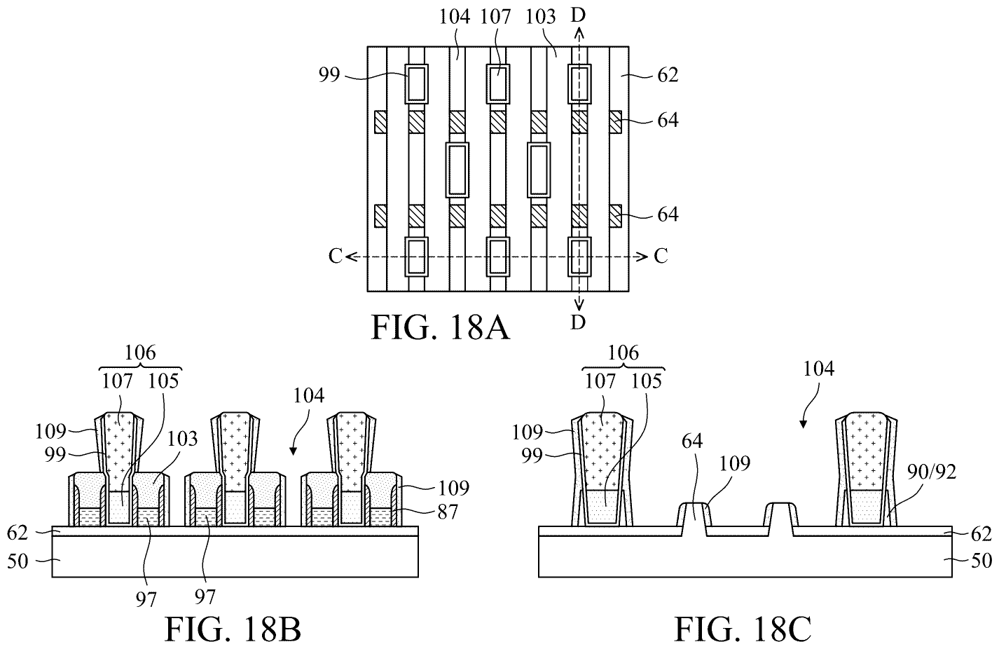

Next, in FIGS. 18A-18C, a liner 109 is formed along sidewalls of the structure shown in FIGS. 17A-17C. The liner 109 may be formed by forming a conformal liner layer (e.g., a dielectric layer) over the structure shown in FIGS. 17A-17C, followed by an anisotropic etch to remove horizontal portions of the liner layer. The liner 109 is formed of a dielectric material, such as SiC, LaO, AlO, AlON, ZrO, HfO, SiN, ZnO, ZrN, ZrAlO, TiO, TaO, YO, TaCN, ZrSi, SiOCN, SiOC, SiCN, HfSi, SiO, or the like, in some embodiments. One difference between the liner 99 and the liner 109 is that the liner 99 has a bottom horizontal portion remained in forming a “U” shape together with vertical portions, while the liner 109 has substantially vertical portions remained only. Also, the liner 99 may be thicker than the liner 109 for about 20% to about 80%, which is more effective to boost time-dependent dielectric break-down (TDDB) performance. In some embodiments, the liner 109 has a thickness ranging from about 0.5 nm to about 5 nm. In other embodiments, forming of the liner 109 is skipped. Further, the liner 99 and the liner 109 may include different material compositions.

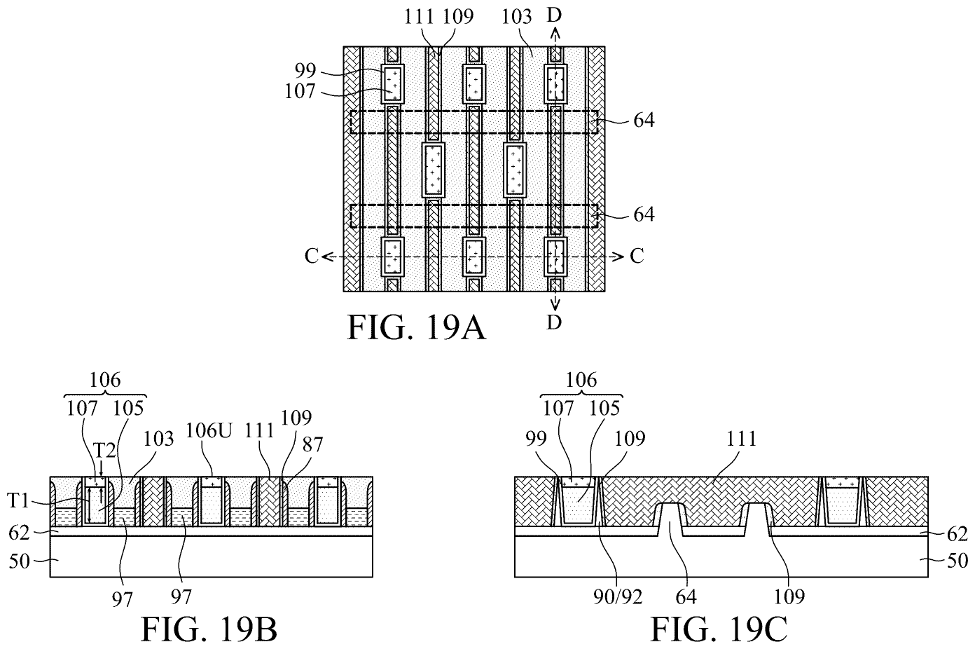

Next, in FIGS. 19A-19C, an electrically conductive material 111, such as Cu, W, Al, Co, the like, or combinations thereof, is formed in the openings 104. Although not illustrated, a barrier layer may be formed conformally along sidewalls and the bottom of the openings 104 before the electrically conductive material 111 is formed. The barrier layer may comprise TiN, TaN, Ti, Ta, or the like, and may be formed using, e.g., PECVD, sputtering, MOCVD, ALD, or the like. Next, a planarization process, such as CMP, is performed to achieve a coplanar upper surface between the electrically conductive material 111 and the dielectric materials 103/107. Note that the planarization process may remove at least upper portions of the dielectric material 107. After the planarization process, a height T1 of the dielectric material 105 is between about 1 nm and about 80 nm, and a height T2 of the dielectric material 107 is between about 2 nm and about 100 nm. An upper surface 106U of the dielectric cut pattern 106 is higher (further from the substrate 50) than the upper surface of the metal gate 97. In some embodiments, the gate spacers 87 remain covered under the dielectric layer 103 and below the upper surface 106U. In some alternative embodiments, the gate spacers 87 are exposed by the planarization process and have an upper surface leveled with the upper surface 106U. A thickness of the liner 99 is between about 1 nm to about 10 nm. A thickness of the liner 109 is between about 0.5 nm and about 5 nm. In some embodiments, the liner 109 is skipped. FIG. 19C illustrates the oxide 90/92 is below a top surface of the dielectric material 105 and fully covered by the liner 109. Note that the dielectric cut patterns 106 separates the electrically conductive material 111 into separate portions (e.g., discrete, non-continuous portions). These separate portions define different electrical connections between the source/drain regions disposed over different fins 64. For example, by defining different locations of the dielectric cut patterns 106, different electrical connections of the source/drain regions may be achieved. The separated electrically conductive materials 111 are also referred to as S/D contacts 111. Also note that the dielectric cut patterns 106 (together with the liner 99) may be wider than the electrically conductive material 111 (together with the liner 109) in a top view, as shown in FIG. 19A. In some alternatively embodiments, the dielectric cut patterns 106 (together with the liner 99) has the same width with the electrically conductive material 111 (together with the liner 109) in a top view.

As feature size continues to shrink in advanced processing nodes, it becomes increasingly challenging to form the dielectric cut patterns 106. To appreciate the advantage of the present disclosure, consider a reference method where cut patterns are formed by simply patterning the first ILD 90 and the dielectric layer 92 using an alternative patterned hard mask layer (not shown), where the alternative patterned hard mask layer is the complementary of the pattern hard mask layer 101 of FIG. 11A. In other words, the alternative patterned hard mask layer comprises small, separate rectangular pieces (e.g., eight pieces) disposed at the locations of the openings 102 in FIG. 12A. However, these small, separate rectangular pieces of the alternative patterned hard mask layer may peel off during the patterning process to form the cut patterns, thereby failing to form the correct cut patterns underneath the alternative patterned hard mask layer, which may result in short circuit of the different portions of the electrically conductive material 111 in subsequent processing.

In contrast, the presently disclosed method avoids the peel-off problem of the reference method, and therefore, the dielectric cut patterns 106 are formed correctly. The size and the materials of the dielectric cut patterns 106 ensure that the dielectric cut patterns 106 are strong enough to survive the subsequent processing. For example, compared with the reference method discussed above, where a dielectric cut pattern is formed by patterning the first ILD 90 and the dielectric layer 92 using an alternative patterned hard mask layer, the presently disclosed dielectric cut pattern 106 is thicker, and therefore, can better withstand the subsequent processing (e.g., etching), thereby reducing or avoiding the peel-off problem. In addition, the material(s) of the dielectric cut patterns 106 together with the liner 99 in the present disclosure have better physical properties than the material of the oxide 90/92 (e.g., silicon oxide). For instance, the material(s) of the dielectric cut patterns 106 together with the liner 99 may be denser, less porous, and/or more resistant to etching (e.g., having slower etch rate). The better physical properties help to prevent the dielectric cut patterns 106 together with the liner 99 from being damaged during the etching process to remove the first ILD 90 and the dielectric layer 92, thus avoiding the short circuit issue discussed above. In addition, the better physical properties of the materials of the dielectric cut patterns 106 improve the time-dependent dielectric break-down (TDDB) performance between adjacent source/drain regions.

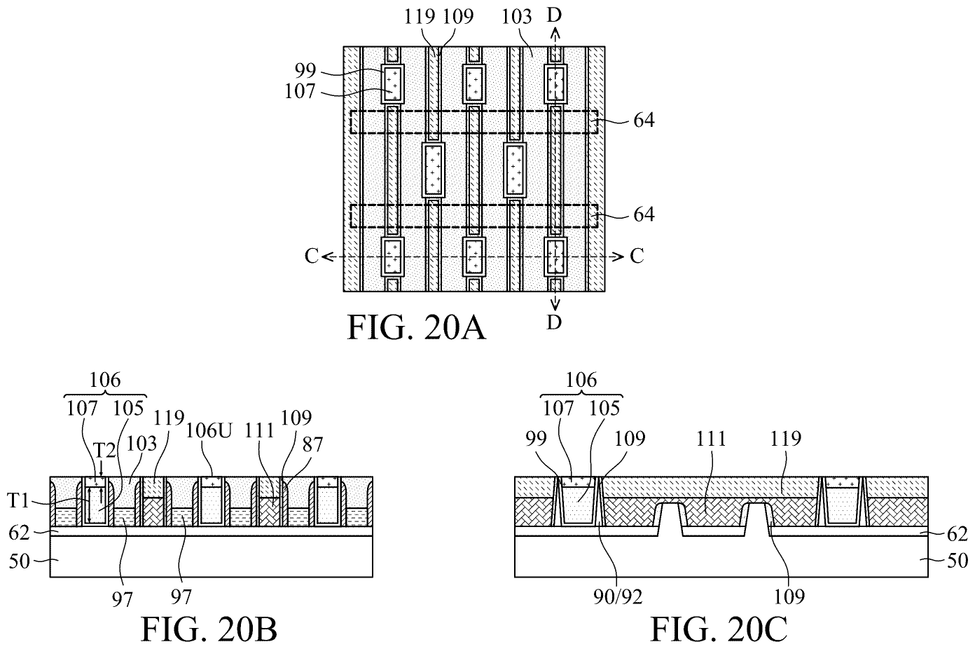

Next, in FIGS. 20A-20C, the electrically conductive material 111 is etched back (e.g., recessed), and a dielectric layer 119 is formed over the (recessed) electrically conductive material 111. The electrically conductive material 111 may be recessed to a level lower than the bottom surface of the dielectric material 107, such that the dielectric layer 119 is thicker than the dielectric material 107. In some embodiments, the dielectric layer 119 is the same (e.g., having a same composition) as the dielectric material 105 and the dielectric layer 103, and the dielectric material 107 is different (e.g., having a different composition) from the dielectric material 105 and the dielectric layer 103. In some embodiments, the dielectric layer 119 comprises SiC, LaO, AlO, AION, ZrO, HO, SiN, Si, ZnO, ZrN, ZrAlO, TiO, TaO, YO, TaCN, ZrSi, SiOCN, SiOC, SiCN, HfSi, SiO, or the like, and is formed by a suitable formation method such as CVD, PVD, the like, or combinations thereof. A planarization process may be performed after the dielectric layer 119 is formed such that the upper surface of the dielectric layer 119 is level with the upper surface of the dielectric layer 103.

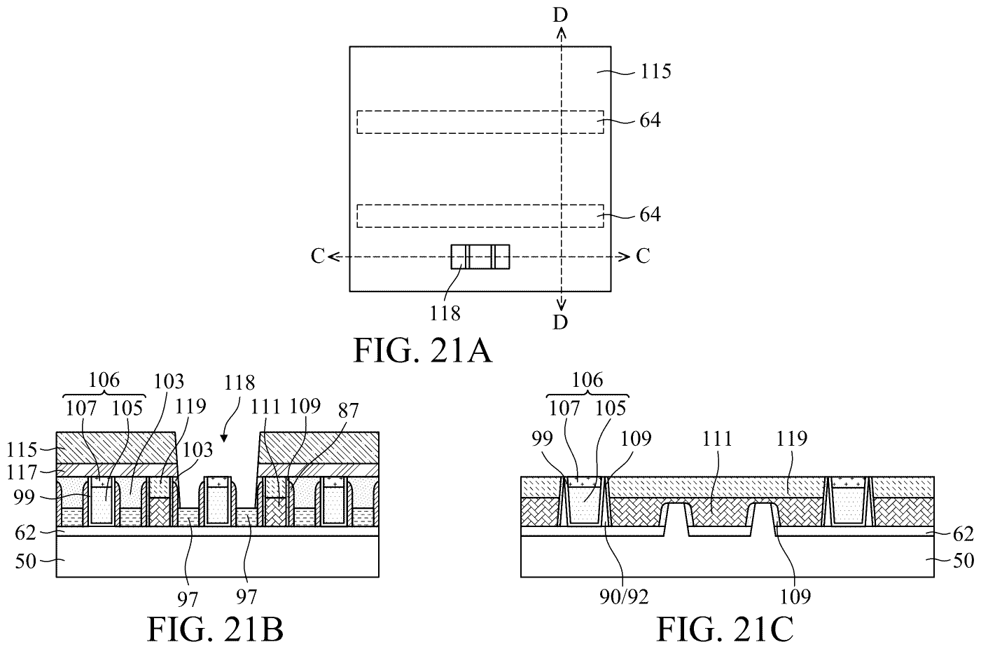

Next, in FIGS. 21A-21C, an etch stop layer 117 is formed over the dielectric cut patterns 106, the dielectric layer 119, and the metal gates 97, and a mask layer 115 is formed over the etch stop layer 117. The etch stop layer 117 may comprise a suitable material such as silicon nitride, silicon carbide, silicon carbonitride, or the like, and may be formed by PVD, CVD, sputtering, or the like. The mask layer 115 may be, e.g., an oxide, and may be formed by any suitable method. Next, an opening 118 is formed in the mask layer 115, e.g., using photolithography and etching techniques. The opening 118 may be extended through the etch stop layer 117. Next, an anisotropic etching process is performed using the patterned mask layer 115 as an etching mask to remove portions of the dielectric layer 103, such that the dielectric cut pattern 106 and the metal gates 97 directly under the opening 118 are exposed. Note that due to the etch selectivity between the dielectric material 107 and the dielectric layer 103, the etching process removes the dielectric layer 103 without substantially attacking the dielectric material 107. In the example of FIG. 21B, residue portions of the dielectric layer 103 is left at the sidewall of the opening 118 between the gate spacers 87 and the etch stop layer 117. Note that the opening 118 exposes a dielectric cut pattern 106, and metal gates 97 on opposing sides of the dielectric cut pattern 106. The upper surface of the dielectric cut pattern 106 is higher (e.g., further from the substrate 50) than the upper surface of the metal gate 97. In the example of FIG. 21A-21C, the dielectric cut pattern 106 includes two different dielectric materials, e.g., an upper layer formed of the dielectric material 107 and a lower layer formed of the dielectric material 105. The bi-layered structure of the dielectric cut pattern 106 provides flexibility in the choice of the dielectric materials. For example, the dielectric material 107 may be chosen to provide etching selectivity between the dielectric material 107 and the dielectric layer 103 during the formation of the opening 118, and the dielectric material 105 may be chosen to offer better TDDB performance between adjacent source/drain regions. The dual-layered structure of the dielectric cut pattern 106 is further surrounded by the liner 99, providing both good TDDB performance (e.g., between adjacent source/drain regions) and the etching selectivity over the dielectric layer 103.

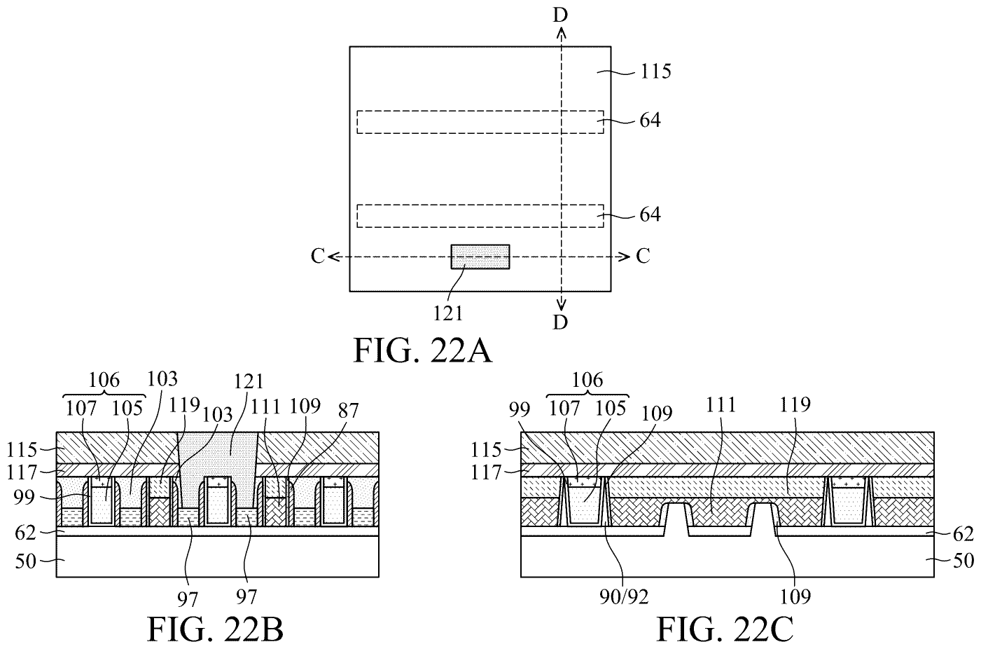

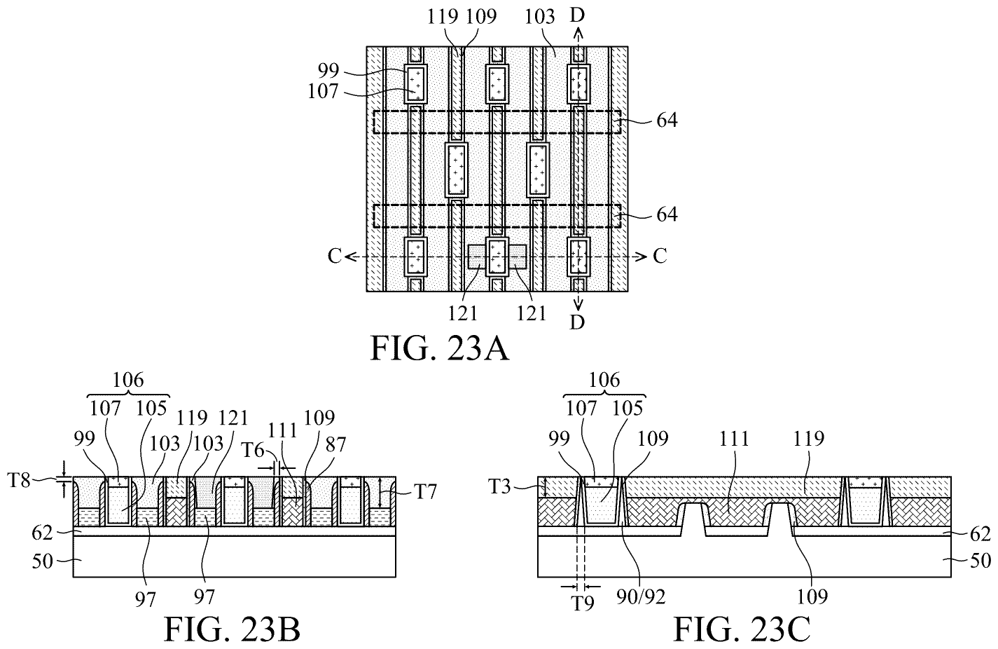

Next, in FIGS. 22A-22C and FIGS. 23A-23C, an electrically conductive material 121 (e.g., Cu, W, Al, Co, or the like) is formed in the opening 118. The electrically conductive material 121 fills the opening 118, and may be formed over the upper surface of the mask layer 115, as shown in FIGS. 22A-22C. Next, the mask layer 115, the etch stop layer 117, and excess portions of the electrically conductive material 121 disposed over the upper surface of the dielectric cut pattern 106 are removed, as shown in FIGS. 23A-23C, e.g., by a CMP process, a dry etch, a wet etch, combination thereof, or the like. As illustrated in FIG. 23B, a coplanar upper surface is achieved between the dielectric material 107, the electrically conductive material 121, the dielectric layer 119, and the dielectric layer 103. Note that the dielectric cut pattern 106 separates the electrically conductive material 121 into two separated gate contacts 121 (also referred to as gate contact plugs), with each gate contact 121 being connected to a respective underlying metal gate 97. Top portions of the two separated gate contacts 121 are in contact with opposing sidewalls of the liner 99, respectively. As illustrated in FIG. 23C, a residue portion of the oxide 90/92 is sandwiched by the liner 99 and the liner 109, while top portions of the liner 99 and the liner 109 are in contact. The residue portion of the oxide 90/92 may be higher than the recessed electrically conductive material 111 in some embodiments. Alternatively, the residue portion of the oxide 90/92 may be below an upper surface of the recessed electrically conductive material 111.

Note that the width of the opening 118 (see FIG. 21A-21C) is larger than the width of each of the gate contacts 121, and the gate contacts 121 are formed in a self-aligned manner using the dielectric cut pattern 106. This illustrates another advantage of the present disclosure. As feature sizes continue to shrink in advanced processing nodes, the resolution of the conventional photolithography may not be enough to form separate opening for each of the gate contacts 121. The disclosed methods allow a larger opening (e.g., 118) to be formed using the conventional photolithography, and the smaller gate contacts (e.g., 121) are formed in a self-aligned manner by separating the fill metal in the opening 118 using the dielectric cut pattern 106. This helps to reduce the manufacturing cost (e.g., less stringent requirement for the photolithography tool), and may also improve production yields (e.g., self-aligned gate contacts are easier to form and less likely to have issues associated with filling high aspect ratio openings).

In some embodiments, a thickness T3 of the dielectric layer 119 is between about 0.5 nm and about 15 nm. A width T6 of the residue portions of the dielectric layer 103 at the sidewall of the gate contact 121 is between about 0 nm and about 30 nm, in some embodiments. A thickness T7 of the dielectric layer 103 over the metal gate 97, measured along the middle of the dielectric layer 103, may be between about 1 nm and about 80 nm. A thickness T8 of the dielectric layer 103, measured at the corner of the dielectric layer 103 (e.g., directly over the gate spacers 87), may be between about 1 nm and about 40 nm. A thickness T9 of the residue oxide 90/92 along the sidewall of the dielectric cut pattern 106 may be between about 0 nm and about 30 nm.

Additional processing may be performed to complete the fabrication of the FinFET device 100, such as forming various features and regions known in the art. For example, subsequent processes may form various contacts, vias, metal lines, and multilayers interconnect features (e.g., metal layers and interlayer dielectrics) on the FinFET device 100, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure.

Variations and modifications to the disclosed embodiment are possible and are fully intended to be included within the scope of the present disclosure. For example, the dielectric cut patterns 106 may be formed of a single dielectric material (e.g., 105) instead of being formed of two different dielectric materials (e.g., 105 and 107), particularly when the single dielectric material (e.g., 105) can provide adequate etching selectivity during etching processes discussed above. As another example, the dielectric layer 119 over the electrically conductive material 111 may be omitted. As yet another example, the liner 109 may be omitted. As an additional example, the etching process to form the opening 102 (see FIGS. 11A-11C) may leave some residue oxide 90/92 at the bottom of the openings 102, such that the residue oxide 90/92 remain between the dielectric cut patterns 106 and the substrate 50. These variations may be combined to form different embodiments, some of which are discussed below.

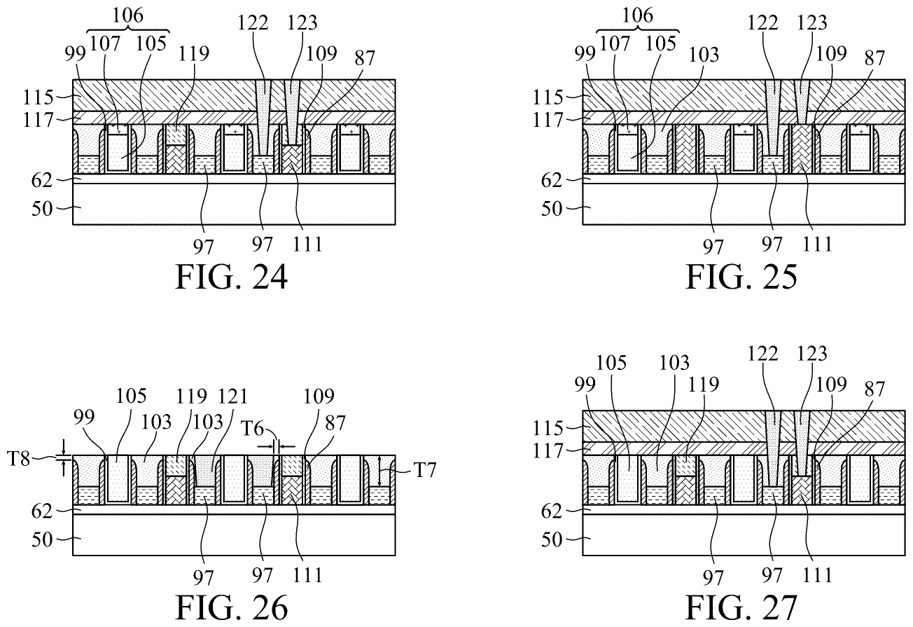

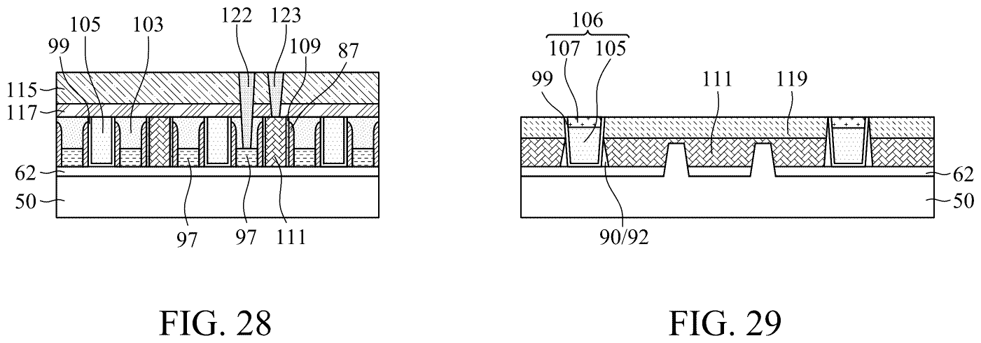

FIGS. 24-29 illustrate various alternative embodiments. FIG. 24 illustrates a cross-sectional view of a FinFET device similar to the FinFET device 100 along cross-section C-C, but with a gate via 122 landing on the metal gate 97 and an S/D via 123 landing on the electrically conductive material 111. To form the gate via 122 and the S/D via 123, via holes may be formed by using photolithography and etching techniques. The via holes extend through the dielectric layer 103 and the dielectric layer 119, respectively. Subsequently, an electrically conductive material fills the via holes and forms the gate via 122 and the S/D via 123. FIG. 25 illustrates a cross-sectional view of a FinFET device similar to the FinFET device in FIG. 24, but without the dielectric layer 119 covering the electrically conductive material 111. FIG. 26 illustrates cross-sectional view of a FinFET device similar to the FinFET device in FIG. 23B, where the dielectric cut patterns 106 may be formed of a single dielectric material (e.g., 105) instead of being formed of two different dielectric materials (e.g., 105 and 107), particularly when the single dielectric material (e.g., 105) can provide adequate etching selectivity during etching processes. FIG. 27 illustrates a cross-sectional view of a FinFET device similar to the FinFET device in FIG. 24, where the dielectric cut patterns 106 may be formed of a single dielectric material (e.g., 105) instead of being formed of two different dielectric materials (e.g., 105 and 107). FIG. 28 illustrates a cross-sectional view of a FinFET device similar to the FinFET device in FIG. 25, where the dielectric cut patterns 106 may be formed of a single dielectric material (e.g., 105) instead of being formed of two different dielectric materials (e.g., 105 and 107). FIG. 29 illustrates a cross-sectional view of a FinFET device similar to the FinFET device in FIG. 23C along the cross-section D-D, but without the liner 109. Note that the oxide 90/92 along the tapered sidewalls of the dielectric cut pattern 106 is recessed, such as below a top surface of the electrically conductive material 111 as illustrated in FIG. 29. This is because a pre-cleaning process (e.g., an etching process) may be performed before the electrically conductive material 111 is formed. The pre-cleaning process may consume a top portion of the oxide 90/92 if the liner 109 is not formed. In embodiments where the liner 109 is formed (e.g., FIG. 23C), the liner 109 protects the oxide 90/92 from the pre-cleaning process, thus the oxide 90/92 substantially remains in the device formed. Similar with the alternative embodiments illustrated in FIGS. 25-27, the dielectric layer 107 and/or dielectric layer 119 may be omitted in the FinFET device as illustrated in FIG. 29.

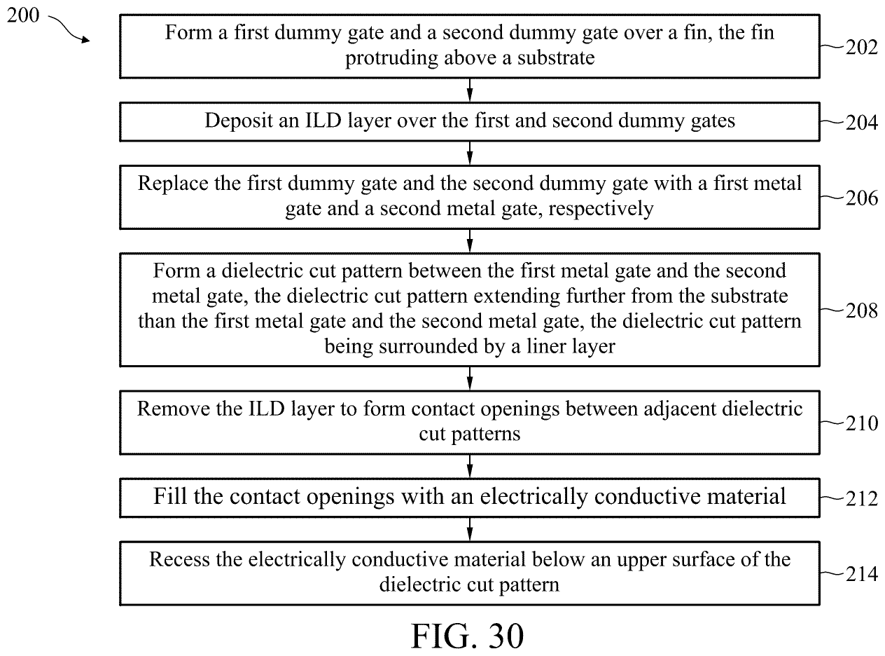

FIG. 30 illustrates a flow chart of a method 200 of fabricating a semiconductor device, in accordance with some embodiments. It should be understood that the embodiment method shown in FIG. 30 is merely an example of many possible embodiment methods. One of ordinary skill in the art would recognize many variations, alternatives, and modifications. For example, various steps as illustrated in FIG. 30 may be added, removed, replaced, rearranged and repeated. At step 202, a first dummy gate and a second dummy gate are formed over a fin, the fin protruding above a substrate. At step 204, an ILD layer is deposited over the first dummy gate and second dummy gate. At step 206, the first dummy gate and the second dummy gate are replaced with a first metal gate and a second metal gate, respectively. At step 208, a dielectric cut pattern is formed between the first metal gate and the second metal gate, the dielectric cut pattern extending further from the substrate than the first metal gate and the second metal gate and surrounded by a liner layer from a top view. At step 210, the ILD is removed to form contact openings between adjacent dielectric cut patterns. At step 212, the contact opening is filled with a electrically conductive material. At step 214, the electrically conductive material is recessed below an upper surface of the dielectric cut pattern distal to the substrate, thereby forming S/D contacts.

Embodiments in the present disclosure may achieve various advantages. The present disclosed methods avoid or reduce the issue of a hard mask layer peel-off during formation of the dielectric cut patterns, thereby avoiding formation of incorrect dielectric cut patterns and electrical short between source/drain regions that are designed to be separated. Due to the improved physical properties of the materials of the dielectric cut patterns, TDDB performance between adjacent source/drain regions of the device is also improved. In addition, the dielectric cut patterns allow source/drain contacts and gate contact plugs to be formed in a self-aligned manner, which allows photolithography tool with lower resolution to be used in forming the conductive connects with close spacing. As a result, production cost is reduced, and production yield is improved.

In one exemplary aspect, the present disclosure is directed to a semiconductor device. The semiconductor device includes a fin protruding from a substrate, a first gate structure and a second gate structure over the fin, a dielectric cut pattern sandwiched by the first and second gate structures, the dielectric cut pattern being spaced apart from the fin, and the dielectric cut pattern extending further from the substrate than a first gate electrode of the first gate structure and a second gate electrode of the second gate structure, a liner layer surrounding the dielectric cut pattern in a top view, and a conductive feature sandwiched by the first and second gate structures, the conductive feature being divided by the dielectric cut pattern into a first segment and a second segment, and the first segment of the conductive feature being above a source/drain region of the fin. In some embodiments, the semiconductor device further includes a dielectric layer over and contacting the first gate electrode and the second gate electrode, a top surface of the dielectric layer being level with a top surface of the dielectric cut pattern. In some embodiments, the semiconductor device further includes a first gate contact plug and a second gate contact plug over and contacting the first gate electrode and the second gate electrode, respectively, top portions of the first gate contact plug and the second gate contact plug being in contact with opposing sidewalls of the liner layer, respectively. In some embodiments, the liner layer is a first liner layer and the semiconductor device further includes a second liner layer surrounding each of the first and second segments of the conductive feature in the top view. In some embodiments, the first liner layer is thicker than the second liner layer. In some embodiments, the first liner layer is in contact with the second liner layer. In some embodiments, the semiconductor device further includes a residue oxide layer sandwiched between bottom portions of the first liner layer and the second liner layer. In some embodiments, a portion of the liner layer is directly under the dielectric cut pattern and separates the dielectric cut pattern from contacting the substrate. In some embodiments, the dielectric cut pattern includes a bottom dielectric layer and a top dielectric layer over the bottom dielectric layer, and compositions of the bottom dielectric layer and the top dielectric layer are different. In some embodiments, a top surface of the bottom dielectric layer is above the first gate electrode and the second gate electrode.

In another exemplary aspect, the present disclosure is directed to a semiconductor device. The semiconductor device includes a metal gate over a channel region of the semiconductor device, a gate spacer on sidewalls of the metal gate, a first liner layer on sidewalls of the gate spacer, a dielectric feature surrounded by the first liner layer in a top view, a top surface of the dielectric feature being above a gate electrode of the metal gate, and a conductive feature divided by the dielectric feature into a first segment over a first source/drain region of the semiconductor device and a second segment over a second source/drain region of the semiconductor device. In some embodiments, the channel region and the first source/drain region are parts of a same transistor, and the second source/drain region is a part of another transistor. In some embodiments, the semiconductor device further includes a second liner layer contacting the first liner layer, the conductive feature being surrounded by the second liner layer in the top view. In some embodiments, the first liner layer is thicker for about 20% to about 80% than the second liner layer. In some embodiments, the first liner layer and the second liner layer include different compositions. In some embodiments, the dielectric feature is above a top surface of the conductive feature.

In another exemplary aspect, the present disclosure is directed to a method. The method includes forming a fin protruding from a substrate, forming a first dummy gate and a second dummy gate over the fin, depositing an interlayer dielectric (ILD) layer over the first and second dummy gates, replacing the first and second dummy gates with first and second metal gates, respectively, patterning the ILD layer, thereby forming an opening between the first and second dummy gates, depositing a first liner layer in the opening, forming a dielectric cut pattern surrounded by the first liner layer, removing the ILD layer, thereby forming a contact trench, and depositing a conductive material in the contact trench, thereby forming a contact sandwiched by the first and second metal gates, wherein the contact is divided by the dielectric cut pattern into a first segment and a second segment. In some embodiments, the method further includes depositing a second liner layer in the contact trench, each of the first and second segments of the contact being surrounded by the second liner layer. In some embodiments, after the removing of the ILD layer, a residue portion of the ILD layer remains on sidewalls of the first liner layer. In some embodiments, the first liner layer is conformally deposited in the opening.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a fin protruding from a substrate;
forming first and second dummy gates across the fin;
depositing a first gate spacer extending along a sidewall of the first dummy gate and a second gate spacer extending along a sidewall of the second dummy gate;
forming a source/drain epitaxial feature over the fin and between the first and second dummy gates;
depositing an interlayer dielectric layer over the source/drain epitaxial feature and between the first and second gate spacers;
replacing the first and second dummy gates with first and second metal gates, respectively;
patterning the interlayer dielectric layer to form an opening between the first and second gate spacers;
forming a dielectric cut feature in the opening;
after the forming of the dielectric cut feature, etching the interlayer dielectric layer to form a first trench between the first and second metal gates; and
forming a first source/drain contact in the first trench, wherein the first source/drain contact is in electrical coupling with the source/drain epitaxial feature.

2. The method of claim 1, wherein the etching of the interlayer dielectric layer also forms a second trench between the first and second metal gates, the method further comprising:
forming a second source/drain contact in the second trench, wherein along a direction perpendicular to a lengthwise direction of the fin the dielectric cut feature is between the first source/drain contact and the second source/drain contact.

3. The method of claim 1, wherein after the patterning of the interlayer dielectric layer the first and second gate spacers are exposed in the opening.

4. The method of claim 1, wherein the dielectric cut feature interfaces with the first and second gate spacers.

5. The method of claim 1, wherein the forming of the dielectric cut feature includes:
conformally depositing a first liner on sidewalls of the opening, and
depositing a dielectric fill layer over the first liner.

6. The method of claim 5, further comprising:
prior to the forming of the first source/drain contact, conformally depositing a second liner on sidewalls of the first trench, wherein the first liner interfaces with the second liner.

7. The method of claim 1, wherein a top surface of the dielectric cut feature is above top surfaces of the first and second metal gates.

8. The method of claim 1, wherein a top surface of the dielectric cut feature is above a top surface of the first source/drain contact.

9. The method of claim 1, further comprising:
performing a planarization process, such that a top surface of the dielectric cut feature is coplanar with a top surface of the first source/drain contact.

10. The method of claim 1, further comprising:
forming a gate contact straddling the dielectric cut feature, wherein the gate contact includes a first leg interfacing with a top surface of the first metal gate and a second leg interfacing with a top surface of the second metal gate.

11. A method, comprising:
forming first and second fin protruding from a substrate;
forming a first source/drain epitaxial feature over the first fin and a second source/drain epitaxial feature over the second fin;
depositing an interlayer dielectric layer over the first and second epitaxial features;
patterning the interlayer dielectric layer to form first and second openings, wherein, in a direction perpendicular to a lengthwise direction of the first and second fins, the first and second source/drain epitaxial features are between the first and second openings;
forming a first dielectric cut feature in the first opening and a second dielectric cut feature in the second opening;
etching the interlayer dielectric layer to form a trench, wherein, in the direction perpendicular to the lengthwise direction of the first and second fins, the trench is between the first and second dielectric cut features; and
forming a source/drain contact in the trench, wherein the source/drain contact is in electrical coupling with both the first and second source/drain epitaxial features.

12. The method of claim 11, wherein the source/drain contact extends lengthwise in the direction perpendicular to the lengthwise direction of the first and second fins.

13. The method of claim 11, wherein the trench exposes the first and second dielectric cut features.

14. The method of claim 11, wherein, measured along the lengthwise direction of the first and second fins, a width of the first and second dielectric cut feature is greater than a width of the source/drain contact.

15. The method of claim 11, wherein the etching of the interlayer dielectric layer to form the trench is after the forming of the first and second dielectric cut features.

16. The method of claim 11, further comprising:
prior to the forming of the source/drain contact, depositing a liner layer on sidewalls of the trench, wherein the liner layer interfaces with the first and second dielectric cut features.

17. A method, comprising:
forming a fin protruding from a substrate;
forming a first dummy gate and a second dummy gate over the fin;
depositing an interlayer dielectric (ILD) layer over the first and second dummy gates;
replacing the first and second dummy gates with first and second metal gates, respectively;
patterning the ILD layer, thereby forming an opening between the first and second dummy gates;
depositing a first liner layer in the opening;
forming a dielectric cut pattern surrounded by the first liner layer;
removing the ILD layer, thereby forming a contact trench; and
depositing a conductive material in the contact trench, thereby forming a contact sandwiched by the first and second metal gates, wherein the contact is divided by the dielectric cut pattern into a first segment and a second segment.

18. The method of claim 17, further comprising:
depositing a second liner layer in the contact trench, wherein each of the first and second segments of the contact is surrounded by the second liner layer.

19. The method of claim 17, wherein after the removing of the ILD layer, a residue portion of the ILD layer remains on sidewalls of the first liner layer.

20. The method of claim 17, wherein the first liner layer is conformally deposited in the opening.
